(19) United States
(12) Patent Application Publication
(10) Pub. No.: US 2019/0250509 A1
(43) Pub. Date: Aug. 15, 2019

(54) PHOTOSENSITIVE COMPOSITION AND ORGANIC THIN-FILM TRANSISTOR

(71) Applicant: SUMITOMO CHEMICAL COMPANY, LIMITED, Tokyo (JP)

(72) Inventors: Takayuki OKACHI, Tsukuba-shi (JP); Eiji Yoshikawa, Tsukuba-shi (JP)

(73) Assignee: SUMITOMO CHEMICAL COMPANY, LIMITED, Tokyo (JP)

(21) Appl. No.: 16/269,096

(22) Filed: Feb. 6, 2019

(30) Foreign Application Priority Data
Feb. 9, 2018 (JP) 2018-021798

(51) Int. Cl. G03F 7/012; G03F 7/004; H01L 51/05; H01L 51/00; G03F 7/20; G03F 7/38

(52) U.S. Cl. CPC G03F 7/012; G03F 7/0048; G03F 7/38; H01L 51/0014; G03F 7/2012; H01L 51/052

(57) ABSTRACT

A photosensitive composition comprising a polymer compound composed of a repeating unit represented by the following formula (1) and at least one repeating unit selected from the group consisting of a repeating unit represented by the following formula (2), a repeating unit represented by the following formula (3) and a repeating unit represented by the following formula (4), and a compound having at least two azide groups:

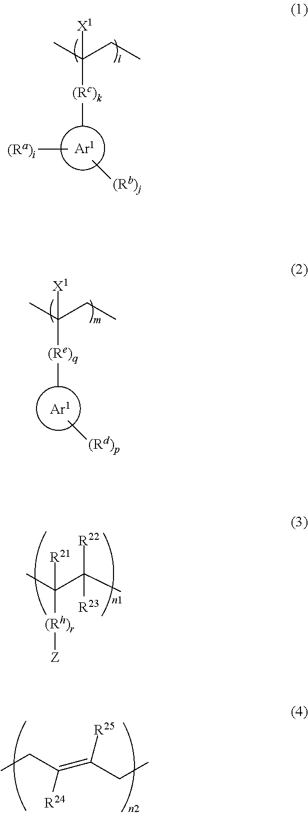

In the formula (1), Ar¹ represents a phenyl group or a naphthyl group, and in the formula (2), Ar² represents a phenyl group or a naphthyl group. l, m, n1 and n2 are numbers satisfying l≥15 and m+n1+n2=100-l, and 1+n2≥10 when the total amount of all repeating units contained in the above-described polymer compound is taken as 100.

### TECHNICAL FIELD

The present invention relates to a photosensitive composition and an organic thin-film transistor.

### BACKGROUND ART

In recent years, patterning of an insulation layer is required in an organic thin-film transistor, and a photosensitive composition is utilized as a composition used in an insulation layer of an organic thin-film transistor.

As the above-described photosensitive composition, for example, a photosensitive composition containing a bisazide compound and polyvinylphenol is reported (Patent Document 1).

### PRIOR ART DOCUMENT

### Patent Document

Patent Document 1: US Patent Application Publication No. 2006/0060841

### SUMMARY OF THE INVENTION

### Problem to be Solved by the Invention

It is required for the above-described photosensitive composition to further improve a patterning property and to be able to produce an organic thin-film transistor exhibiting high carrier mobility by being used in an insulation layer.

The present invention has an object of providing a photosensitive composition having a good patterning property and capable of producing an organic thin-film transistor exhibiting high carrier mobility by being used in an insulation layer.

### Means for Solving the Problem

That is, the present invention provides the following [1] to [14].

[1] A photosensitive composition comprising a polymer compound composed of a repeating unit represented by the following formula (1) and at least one repeating unit selected from the group consisting of a repeating unit represented by the following formula (2), a repeating unit represented by the following formula (3) and a repeating unit represented by the following formula (4), and a compound having at least two azide groups:

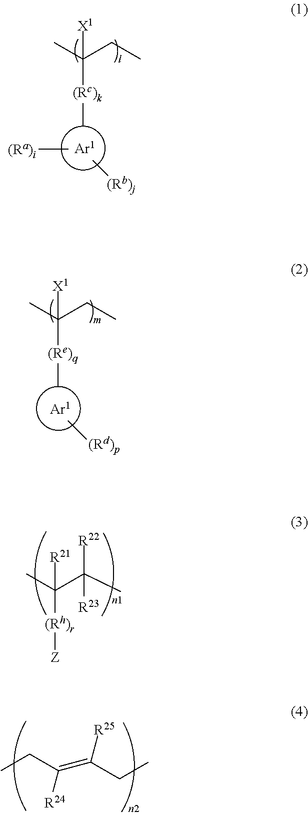

In the formula (1), Ar¹ represents a phenyl group or a naphthyl group.

R^{a} is a group represented by the following formula (5). When a plurality of R^{a} are present, they may be the same or different and may be combined together to form a ring together with a carbon atom on Ar¹ to which they are attached.

R^{b} is a hydrogen atom, a fluorine atom, a phenyl group optionally having a substituent, a naphthyl group optionally having a substituent or a group represented by the following formula (6). When a plurality of R^{b} are present, they may be the same or different.

When Ar¹ is a phenyl group, i represents an integer of 1 to 5 and j represents an integer of 5-i.

When Ar¹ is a naphthyl group, i represents an integer of 1 to 7 and j represents an integer of 7-i.

X¹ represents a hydrogen atom or a methyl group.

R^{c} represents a divalent organic group having a number of carbon atoms of 1 to 20, a group represented by —O— or a group represented by —C(═O)—.

k represents an integer of 0 to 6.

In the formula (2), Ar² represents a phenyl group or a naphthyl group.

A plurality of R^{d} are each a hydrogen atom, a fluorine atom, a phenyl group optionally having a substituent, a naphthyl group optionally having a substituent or a group represented by the following formula (6). A plurality of R^{d} may be the same or different.

When Ar² is a phenyl group, p represents 5.

When Ar² is a naphthyl group, p represents 7.

X² represents a hydrogen atom or a methyl group.

R^{e} represents a divalent organic group having a number of carbon atoms of 1 to 20, a group represented by —O— or a group represented by —C(═O)—.

q represents an integer of 0 to 6.

In the formula (3), R^{2 1}, R^{2 2} and R^{2 3} are each independently a hydrogen atom, a fluorine atom or an alkyl group having a number of carbon atoms of 1 to 20, and R^{2 1}, R^{2 2}, R²³ and Z may be combined together to form a ring.

Z represents an alkyl group having a number of carbon atoms of 1 to 20 or an alkenyl group having a number of carbon atoms of 2 to 20.

A hydrogen atom contained in the group represented by Z may be substituted with a fluorine atom.

R^{h} represents a divalent organic group having a number of carbon atoms of 1 to 20, a group represented by —O— or a group represented by —C(═O)—.

r represents an integer of 0 to 6.

In the formula (4), R^{2 4} and R^{2 5} each independently represent a hydrogen atom or an alkyl group having a number of carbon atoms of 1 to 20.

l, m, n1 and n2 are numbers satisfying l≥15 and m+n1+n2=100-l, and 1+n2≥10 when the total amount of all repeating units contained in the above-described polymer compound is taken as 100.

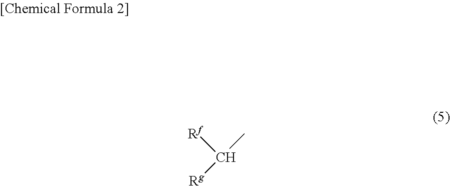

In the formula (5), R^{f} and R^{g} are each independently a hydrogen atom, a fluorine atom or a hydrocarbon group optionally substituted with a fluorine atom, and R^{f} and R^{g} may be combined together to form a ring.

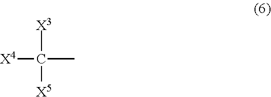

In the formula (6), X³, X⁴ and X⁵ are each independently a fluorine atom or a hydrocarbon group optionally substituted with a fluorine atom.

[2] The photosensitive composition according to [1], wherein in the above-described polymer compound, Ar¹ in the repeating unit represented by the formula (1) is a phenyl group.

[3] The photosensitive composition according to [1] or [2], wherein in the above-described polymer compound, Ar² in the repeating unit represented by the formula (2) is a phenyl group.

[4] The photosensitive composition according to any one of [1] to [3], wherein in the above-described repeating unit represented by the formula (1), the group represented by R^{a} is a methyl group.

[5] The photosensitive composition according to any one of [1] to [4], wherein in the above-described repeating unit represented by the formula (1), k is 0.

[6] The photosensitive composition according to any one of [1] to [5], wherein in the above-described repeating unit represented by the formula (3), r is 0 to 3.

[7] The photosensitive composition according to any one of [1] to [6], wherein the above-described compound having at least two azide groups is a compound represented by the following formula (7).

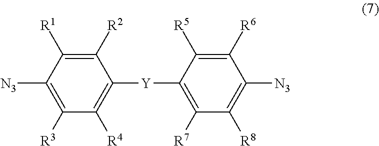

In the formula (7),

R¹ to R⁸ each independently represent a hydrogen atom, a fluorine atom, an alkyl group having a number of carbon atoms of 1 to 5, an alkoxy group having a number of carbon atoms of 1 to 5 or a group represented by SO₃M, wherein M represents a hydrogen atom, an alkali metal atom, an alkyl group having a number of carbon atoms of 1 to 10 or NR^{A}R^{B}, and R^{A} and R^{B} each independently represent a hydrogen atom, an alkyl group having a number of carbon atoms of 1 to 10, a hydroxyalkyl group having a number of carbon atoms of 1 to 10, an alkoxyalkyl group having a number of carbon atoms of 1 to 10 or a hydroxyalkoxyalkyl group having a number of carbon atoms of 1 to 10.

Y represents a single bond, a group represented by —C(=O)—, a group represented by —S—, an alkylene group having a number of carbon atoms of 1 to 8 or a divalent group represented by any one of the following formula (7-1) to the following formula (7-4), wherein in the formula (7-4), R⁹ is a hydrogen atom or an alkyl group having a number of carbon atoms of 1 to 10.

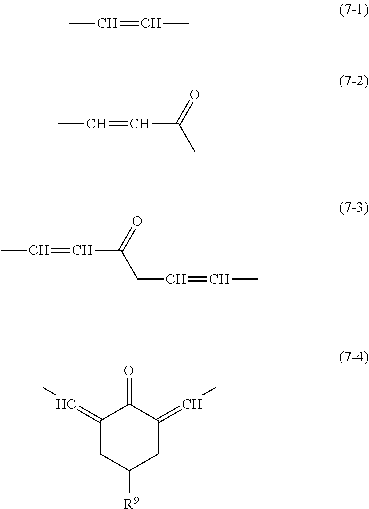

[8] An ink comprising the photosensitive composition according to any one of [1] to [7] and an organic solvent.

[9] A film obtained by hardening the photosensitive composition according to any one of [1] to [7].

[10] An electronic device comprising the film according to [9].

[11] An organic thin-film transistor comprising the film according to [9] as an insulation layer.

[12] An organic thin-film transistor comprising the film according to [9] as a gate insulation layer.

[13] A production method of a hardened film, comprising a step of applying the ink according to [8] on an object to obtain a film,

a step of heating the above-described film to remove the organic solvent, and

a step of exposing the above-described organic solvent-removed film.

[14] A production method of an organic thin-film transistor having an insulation layer, a source electrode, a drain electrode, a gate electrode and an organic semiconductor layer, comprising

a step of forming an insulation layer composed of the hardened film obtained by the production method according to [13],

a step of forming a source electrode, a drain electrode and a gate electrode, and

a step of forming an organic semiconductor layer.

### Effect of the Invention

According to the present invention, it is possible to provide a photosensitive composition having a good patterning property and capable of producing an organic thin-film transistor exhibiting high carrier mobility by being used in an insulation layer.

### BRIEF EXPLANATION OF DRAWINGS

FIG. 1 is a schematic view schematically showing the structure of a bottom gate top contact type organic thin-film transistor.

FIG. 2 is a schematic view schematically showing the structure of a bottom gate bottom contact type organic thin-film transistor.

FIG. 3 is a schematic view schematically showing the structure of a top gate bottom contact type organic thin-film transistor.

FIG. 4 is a schematic view schematically showing the structure of a top gate top contact type organic thin-film transistor.

### MODES FOR CARRYING OUT THE INVENTION

Next, embodiments of the present invention will be described in more detail. It is to be noted that each of the referenced drawings is merely schematically showing the shape, size and arrangement of the constituent elements to the extent that the invention can be understood. The present invention is not limited by the following description, and each component can be appropriately changed without departing from the gist of the present invention. In the drawings used for explanation, the same components are denoted by the same reference numerals, and overlapping explanations may be omitted. Further, the configuration according to the embodiment of the present invention is not necessarily manufactured or used with the arrangement shown in the drawings.

### <Explanation of Common Terms>

Terms commonly used in the present specification have the following meanings unless otherwise stated.

“The polymer compound” denotes a compound having a polystyrene-equivalent number-average molecular weight of 1,000 or more.

“The repeating unit” denotes a unit structure occurring twice or more in a polymer compound.

“The halogen atom” is a fluorine atom, a chlorine atom, a bromine atom or an iodine atom.

“The divalent organic group having a number of carbon atoms of 1 to 20” may be any of linear, branched or cyclic form, and may be an aliphatic hydrocarbon group or an aromatic hydrocarbon group.

The divalent organic group having a number of carbon atoms of 1 to 20 includes, for example, a divalent linear aliphatic hydrocarbon group having a number of carbon atoms of 1 to 20, a divalent branched aliphatic hydrocarbon group having a number of carbon atoms of 3 to 20, a divalent alicyclic hydrocarbon group having a number of carbon atoms of 3 to 20 and a divalent aromatic hydrocarbon group having a number of carbon atoms of 6 to 20.

A hydrogen atom contained in these groups may be substituted with an alkyl group having a number of carbon atoms of 1 to 20, a cycloalkyl group having a number of carbon atoms of 3 to 20, an alkoxy group having a number of carbon atoms of 1 to 20, a cycloalkoxy group having a number of carbon atoms of 3 to 20, a monovalent aromatic hydrocarbon group having a number of carbon atoms of 6 to 20 or a halogen atom.

Of them, the divalent organic group having a number of carbon atoms of 1 to 20 is preferably a divalent linear aliphatic hydrocarbon group having a number of carbon atoms of 1 to 6, a divalent branched aliphatic hydrocarbon group having a number of carbon atoms of 3 to 6, a divalent alicyclic hydrocarbon group having a number of carbon atoms of 3 to 6 or a divalent aromatic hydrocarbon group having a number of carbon atoms of 6 to 10.

A hydrogen atom contained in these groups may be substituted with an alkyl group having a number of carbon atoms of 1 to 20, a cycloalkyl group having a number of carbon atoms of 3 to 20, an alkoxy group having a number of carbon atoms of 1 to 20, a cycloalkoxy group having a number of carbon atoms of 3 to 20, a monovalent aromatic hydrocarbon group having a number of carbon atoms of 6 to 20 or a halogen atom.

Specific examples of the divalent aliphatic hydrocarbon group and the divalent alicyclic hydrocarbon group include a methylene group, an ethylene group, a n-propylene group, an isopropylene group, a cyclopropylene group, a n-butylene group, an isobutylene group, a s-butylene group, a t-butylene group, a cyclobutylene group, a 1-methyl-cyclopropylene group, a 2-methyl-cyclopropylene group, a n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene group, a 1-ethyl-n-propylene group, a cyclopentylene group, a n-hexylene group, a 1-methyl-n-pentylene group, a cyclohexylene group, a 1-methyl-cyclopentylene group, a 2-methyl-cyclopentylene group, a 3-methyl-cyclopentylene group and the like.

Specific examples of the divalent aromatic hydrocarbon group having a number of carbon atoms of 6 to 20 include a phenylene group, a naphthylene group, an anthrylene group, a dimethylphenylene group, a trimethylphenylene group, an ethylenephenylene group, a diethylenephenylene group, a triethylenephenylene group, a propylenephenylene group, a butylenephenylene group, a methylnaphthylene group, a dimethylnaphthylene group, a trimethylnaphthylene group, a vinylnaphthylene group, an ethenylnaphthylene group, a methylanthrylene group, an ethylanthrylene group and the like.

### <Photosensitive Composition>

The photosensitive composition of the present invention is a photosensitive composition comprising a polymer compound composed of the above-described repeating unit represented by the formula (1) and a repeating unit represented by at least one formula selected from the group consisting of the formula (2), the formula (3) and the formula (4), and a compound having at least two azide groups.

The photosensitive composition of the present invention may contain additives which are usually used in cross-linking a polymer compound, as other components. The additives include a catalyst for promoting a cross-linking reaction, a leveling agent, a viscosity modifier, a surfactant and the like.

<Polymer Compound Composed of the Above-Described Repeating Unit Represented by the Formula (1) and a Repeating Unit Represented by at least One Formula Selected from the Group Consisting of the Formula (2), the Formula (3) and the Formula (4)>

The above-described polymer compound contained in the photosensitive composition of the present invention is a polymer compound comprising the above-described repeating unit represented by the formula (1) and a repeating unit represented by at least one formula selected from the group consisting of the formula (2), the formula (3) and the formula (4), wherein when the total amount of all repeating units contained in the above-described polymer compound is taken as 100, the content of the above-described repeating unit represented by the formula (1) is expressed as l≥15, the total amount of repeating units represented by the formula (2), the formula (3) and the formula (4) is expressed as m+n1+n2=100-l and the total amount of repeating units represented by the formula (3) and the formula (4) is expressed as n1+n2≥10.

In the above-described polymer compound contained in the above-described photosensitive composition, the above-described repeating unit represented by the formula (1), the above-described repeating unit represented by the formula (2), the above-described repeating unit represented by the formula (3) or the above-described repeating unit represented by the formula (4) may each be contained in combination of two or more kinds thereof.

The content of the repeating unit represented by the formula (1) in the above-described polymer compound is preferably expressed as l≥50, more preferably expressed as l≥80 when the total amount of all repeating units contained in the above-described polymer compound is taken as 100.

The photosensitive composition of the present invention containing the above-described polymer compound in which the content of the repeating unit represented by the formula (1) is within the above-described range is excellent in a patterning property and further is capable of producing an organic thin-film transistor exhibiting high carrier mobility by using an insulation layer composed of the photosensitive composition.

The total amount of repeating units represented by the formula (3) and the formula (4) in the above-described polymer compound is preferably expressed as n1+n2≥20.

An organic thin-film transistor exhibiting high carrier mobility can be produced by using an insulation layer composed of the photosensitive composition of the present invention containing the above-described polymer compound in which the total amount of repeating units represented by the formula (3) and the formula (4) is within the above-described range.

The content of the above-described repeating units contained in the polymer compound is determined from the use amount of raw material monomers corresponding to repeating units used in production of the polymer compound.

Hereinafter, the repeating unit represented by the formula (1) described above will be explained.

In the formula (1), Ar¹ represents a phenyl group or a naphthyl group, preferably a phenyl group.

In the formula (1), R^{a} is represented by the above-described formula (5), and a plurality of R^{a} may be present. When a plurality of R^{a} are present, they may be the same or different and may be combined together to form a ring together with a carbon atom on Ar¹ to which they are attached.

In the above-described formula (5), R^{f} and R^{g} are each independently a hydrogen atom, a fluorine atom or a hydrocarbon group optionally substituted with a fluorine atom, and may be combined together to form a ring.

It is preferable that at least one of R^{f} and R^{g} is a hydrogen atom, it is more preferable that both R^{f} and R^{g} represent a hydrogen atom. A film obtained by hardening the photosensitive composition of the present invention containing the above-described polymer compound having the repeating unit represented by the formula (1) as described above is excellent in a patterning property.

In the formula (1), R^{b} is a hydrogen atom, a fluorine atom, a phenyl group optionally having a substituent, a naphthyl group optionally having a substituent or a group represented by the above-described formula (6), and a plurality of R^{b} may be present.

When a plurality of R^{b} are present, they may be the same or different. R^{b} is preferably a hydrogen atom, a fluorine atom or a trifluoromethyl group, more preferably a hydrogen atom or a fluorine atom, particularly preferably a hydrogen atom.

In the above-described formula (6), X³, X⁴ and X⁵ are each independently a fluorine atom or a hydrocarbon group optionally substituted with a fluorine atom, and the hydrocarbon group optionally substituted with a fluorine atom includes a trifluoromethyl group, a 1,1-difluoroethyl group, a pentafluoroethyl group, a perfluoropropyl group, a perfluorobutyl group, a perfluorohexyl group, a perfluorooctyl group and the like.

When R^{b} is a phenyl group, the phenyl group may have a fluorine atom, a tert-butyl group, a trifluoromethyl group, a phenyl group or the like as the substituent, and preferably has a fluorine atom.

When R^{b} is a naphthyl group, the naphthyl group may have a fluorine atom, a tert-butyl group, a trifluoromethyl group, a phenyl group or the like as the substituent, and preferably has a fluorine atom.

When Ar¹ is a phenyl group, i represents an integer of 1 to 5 and j represents an integer of 5-i. i is preferably 1 to 3, more preferably 1. An organic thin-film transistor containing a film obtained by hardening the photosensitive composition of the present invention containing the above-described polymer compound having the repeating unit represented by the formula (1) as described above exhibits improved carrier mobility.

When Ar¹ is a naphthyl group, i represents an integer of 1 to 7 and j represents an integer of 7-i. i is preferably 1 to 3, more preferably 1. An organic thin-film transistor containing a film obtained by hardening the photosensitive composition of the present invention containing the above-described polymer compound having the repeating unit represented by the formula (1) as described above exhibits improved carrier mobility.

In the formula (1), X¹ represents a hydrogen atom or a methyl group, preferably a hydrogen atom.

In the formula (1), k represents an integer of 0 to 6. k is preferably an integer of 0 to 3, k is more preferably 0.

In the formula (1), R^{c} represents a divalent organic group having a number of carbon atoms of 1 to 20, a group represented by —O— or a group represented by —C(═O)—. R^{c} is preferably a methylene group, a group represented by —O— or a group represented by —C(═O)—.

Examples of monomers as the raw material of the repeating unit represented by the formula (1) include o-methylstyrene, m-methylstyrene, p-methylstyrene, 2,3-dimethylstyrene, 2,4-dimethylstyrene, 2,5-dimethylstyrene, 2,6-dimethylstyrene, 2,4-dimethyl-α-methylstyrene, 3,4-dimethylstyrene, 3,5-dimethylstyrene, 2,4,6-trimethylstyrene, 2,4,5-trimethylstyrene, pentamethylstyrene, o-ethylstyrene, m-ethylstyrene, p-ethylstyrene, o-octylstyrene, m-octylstyrene, p-octylstyrene, o-isopropenyltoluene, m-isopropenyltoluene, p-isopropenyltoluene, 2,4-dimethyl-α-methylstyrene, 2,3-dimethyl-α-methylstyrene, 3,5-dimethyl-α-methylstyrene, p-isopropyl-α-methylstyrene, diisopropylbenzene, 4-fluoro-2,6-dimethylstyrene, 1-vinyl-2-methylnaphthalene, 1-vinyl-3-methylnaphthalene, 1-vinyl-4-methylnaphthalene, 1-vinyl-5-methylnaphthalene, 1-vinyl-6-methylnaphthalene, 1-vinyl-7-methylnaphthalene, 1-vinyl-8-methylnaphthalene, 2-vinyl-1-methylnaphthalene, 2-vinyl-3-methylnaphthalene, 2-vinyl-4-methylnaphthalene, 2-vinyl-5-methylnaphthalene, 2-vinyl-6-methylnaphthalene, 2-vinyl-7-methylnaphthalene, 2-vinyl-8-methylnaphthalene, 2-fluoro-4-methylstyrene, 3-fluoro-4-methylstyrene, 2,6-difluoro-4-methylstyrene, 4-trifluoromethyl-2,3,5,6-tetramethylstyrene, 2,6-difluoromethyl-4-ethyl-α-methylstyrene, 1-vinyl-3-fluoro-5-methylnaphthalene, 2-vinyl-3-methyl-7,8-ditrifluoromethylnaphthalene, 2-methylbenzyl acrylate, 3-methylbenzyl acrylate, 4-methylbenzyl acrylate, 2-methylbenzyl methacrylate, 3-methylbenzyl methacrylate, 4-methylbenzyl methacrylate, 3-ethylbenzyl acrylate, 4-octylbenzyl acrylate, 3,5-dimethylbenzyl acrylate, 2,4,6-trimethylbenzyl methacrylate, 2-methyl-3-fluorobenzyl acrylate, 2-methyl-4-fluorobenzyl methacrylate, 4-methylphenyl methacrylate, vinyl-4-methylbenzoate, 4-methylphenyl vinyl ether and the like.

Specific examples of the repeating unit represented by the formula (1) are shown below, but the present embodiment is not limited to them.

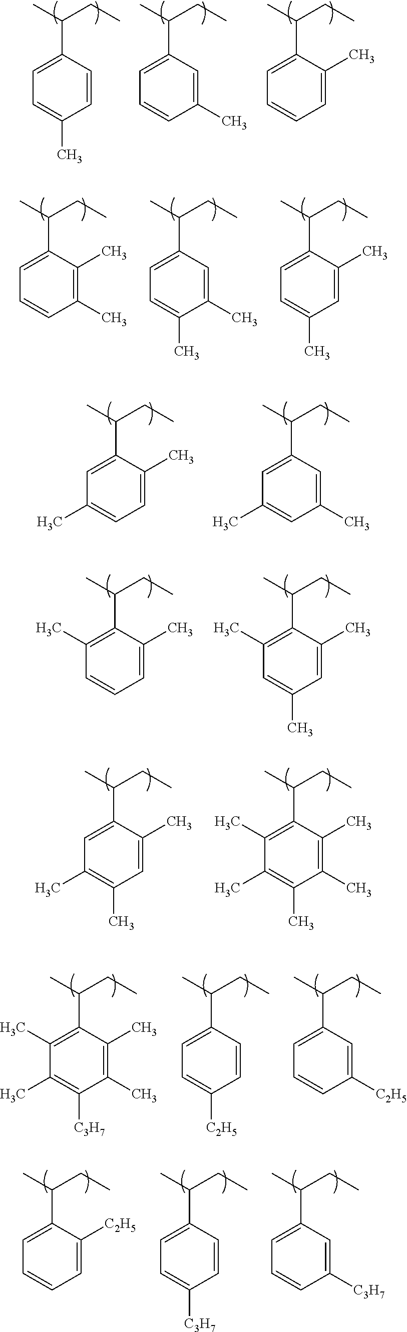

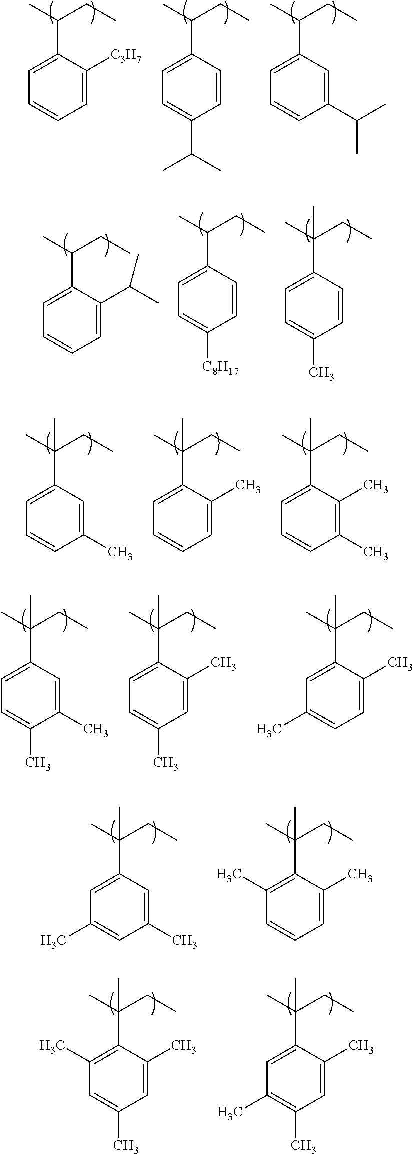

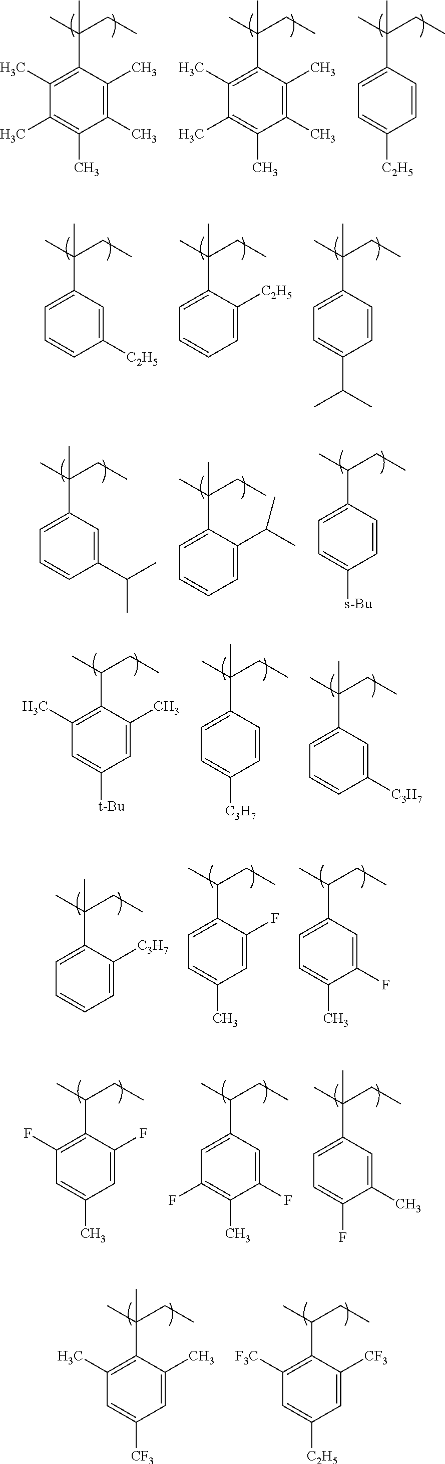

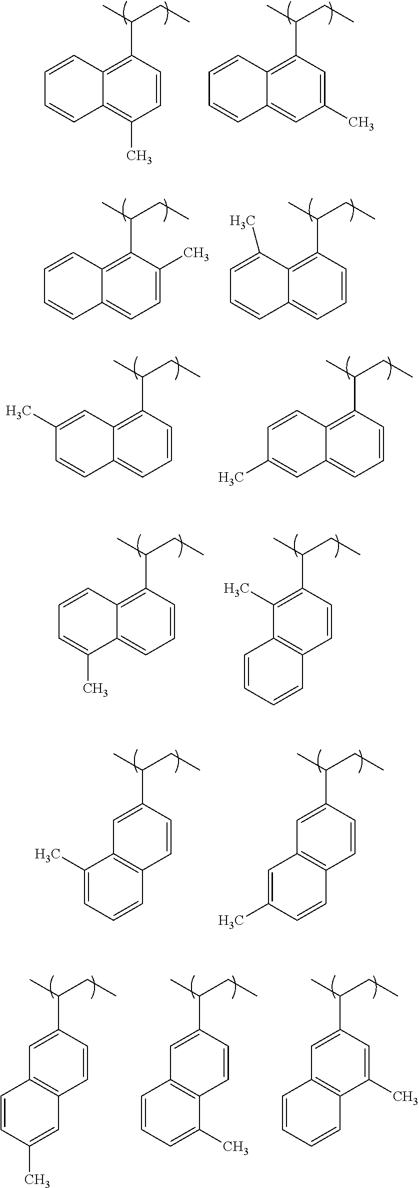

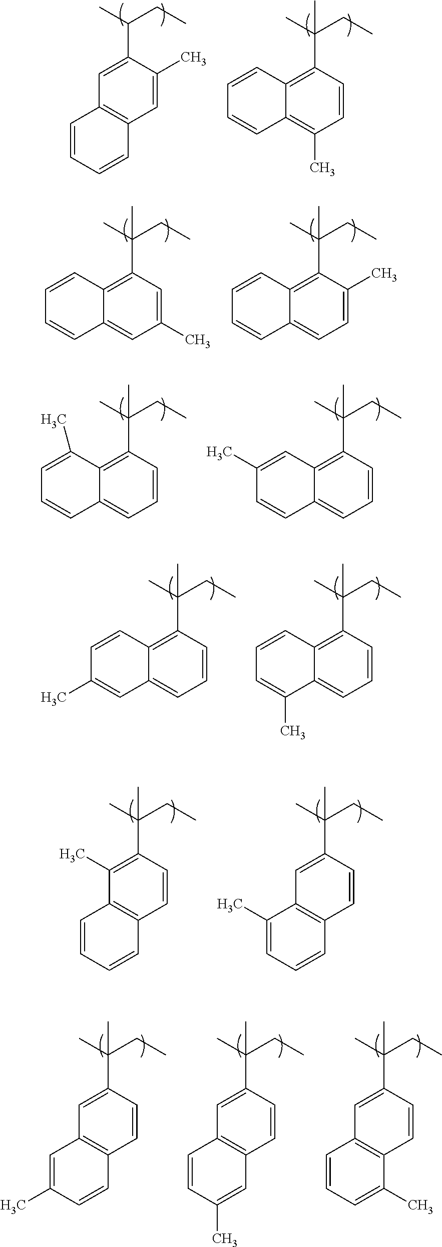

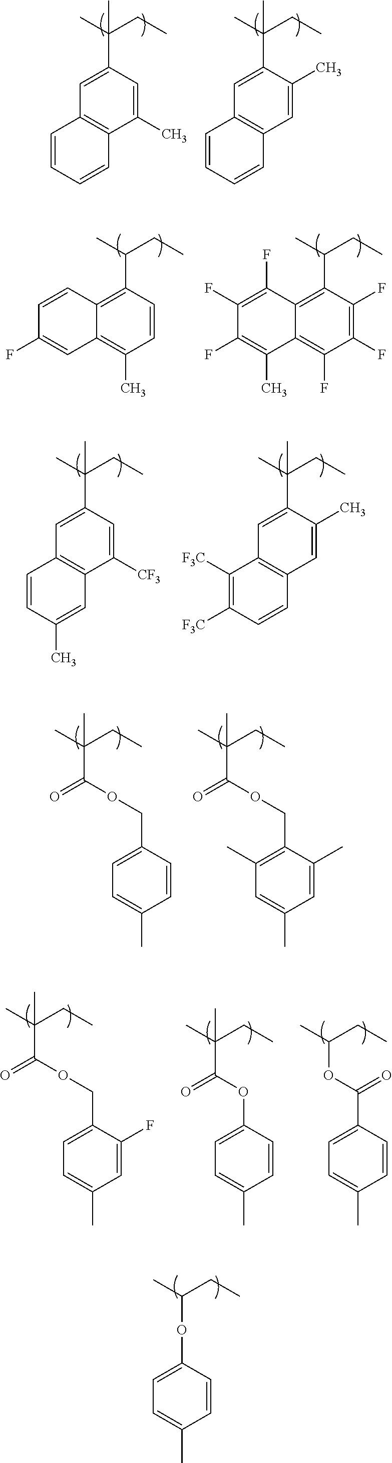

Hereinafter, the repeating unit represented by the formula (2) will be explained.

In the formula (2), Ar² represents a phenyl group or a naphthyl group, preferably a phenyl group.

In the formula (2), R^{d} is a hydrogen atom, a fluorine atom, an optionally substituted aryl group having a number of carbon atoms of 6 to 10 or a group represented by the formula (6), and a plurality of R^{d} may be the same or different. R^{d} is preferably a hydrogen atom, a fluorine atom or a trifluoromethyl group, more preferably a hydrogen atom or a fluorine atom.

In the formula (2), R^{d} is a hydrogen atom, a fluorine atom, a phenyl group optionally having a substituent, a naphthyl group optionally having a substituent or a group represented by the formula (6), and a plurality of R^{d} may be the same or different.

In the above-described formula (6), X³, X⁴ and X⁵ are each independently a fluorine atom or a hydrocarbon group optionally substituted with a fluorine atom, and the hydrocarbon group optionally substituted with a fluorine atom includes a trifluoromethyl group, a 1,1-difluoroethyl group, a pentafluoroethyl group, a perfluoropropyl group, a perfluorobutyl group, a perfluorohexyl group, a perfluorooctyl group and the like.

When R^{d} is a phenyl group, the phenyl group may have a fluorine atom, a tert-butyl group, a trifluoromethyl group, a phenyl group and the like as the substituent, and preferably has a fluorine atom.

When R^{d} is a naphthyl group, the naphthyl group may have a fluorine atom, a tert-butyl group, a trifluoromethyl group, a phenyl group and the like as the substituent, and preferably has a fluorine atom.

In the formula (2), X² represents a hydrogen atom or a methyl group.

In the formula (2), R^{e} represents a divalent organic group having a number of carbon atoms of 1 to 20, a group represented by —O— or a group represented by —C(═O)—. R^{e} is preferably a methylene group, a group represented by —O— or a group represented by —C(═O)—.

In the formula (2), q represents an integer of 0 to 6. q is preferably an integer of 0 to 3.

Examples of monomers as the raw material of the repeating unit represented by the formula (2) include styrene, 4-tert-butylstyrene, 2-vinylbiphenyl, 3-vinylbiphenyl, 4-vinylbiphenyl, 4-vinyl-p-terphenyl, α-methylstyrene, benzyl methacrylate, 2-trifluoromethylstyrene, 3-trifluoromethylstyrene, 4-trifluoromethylstyrene, 2,3,4,5,6-pentafluorostyrene, 2-fluorostyrene, 3-fluorostyrene, 4-fluorostyrene, 2-fluoro-α-methylstyrene, 3-fluoro-α-methylstyrene, 4-fluoro-α-methylstyrene, 4-trifluoromethyl-α-methylstyrene, 2,3,4,5,6-pentafluorobenzyl acrylate, 2,3,4,5,6-pentafluorobenzyl methacrylate, 2-fluorobenzyl acrylate, 2-fluorobenzyl methacrylate, 3-fluorobenzyl acrylate, 3-fluorobenzyl methacrylate, 4-fluorobenzyl acrylate, 4-fluorobenzyl methacrylate, 4-trifluoromethylbenzyl acrylate, 4-trifluoromethylbenzyl methacrylate, 3-(4-fluorophenyl)-1-propene, 3-pentafluorophenyl-1-propene, 3-(4-trifluoromethylphenyl)-1-propene, (4-fluorophenyl) acrylate, (4-fluorophenyl) methacrylate, pentafluorophenyl acrylate, pentafluorophenyl methacrylate, 2-(pentafluorophenyl) ethyl acrylate, 2-(pentafluorophenyl) ethyl methacrylate, 2-(4-fluorophenyl)ethyl acrylate, 2-(4-fluorophenyl)ethyl methacrylate, 2,3,4,5,6-pentafluorophenyl methacrylate, vinyl benzoate, phenylvinyl ether and the like.

Specific examples of the repeating unit represented by the formula (2) are shown below, but the present embodiment is not limited to them.

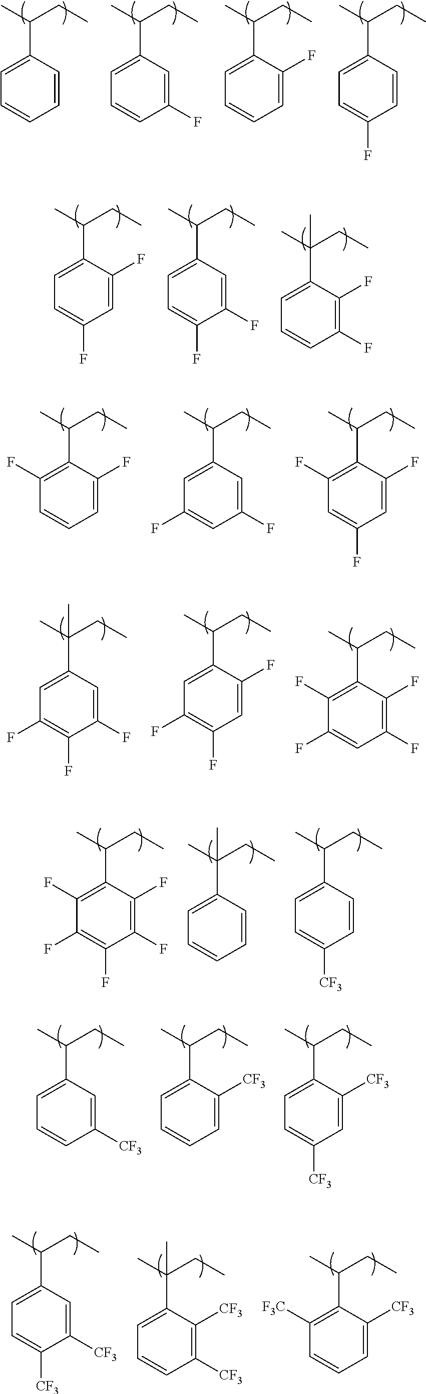

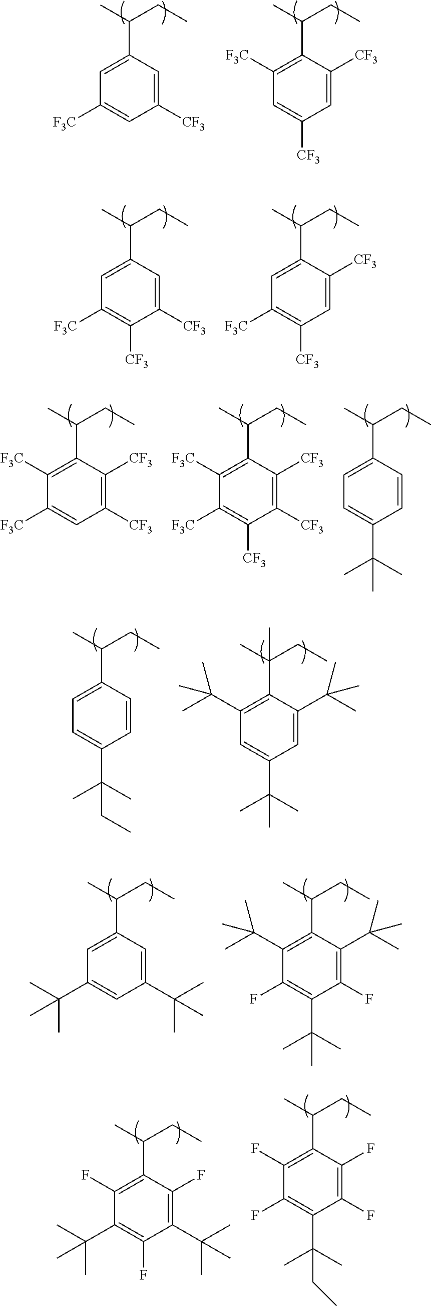

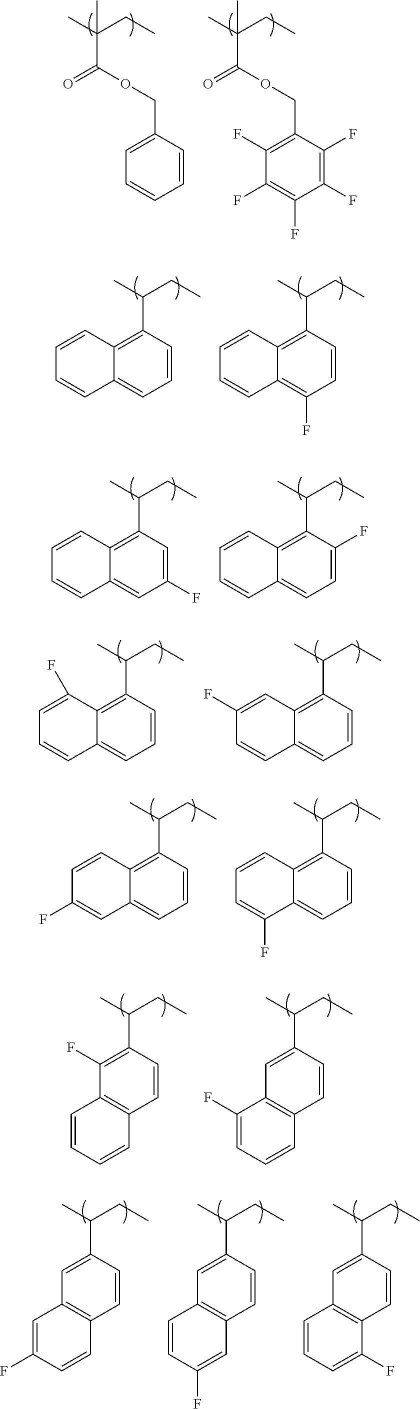

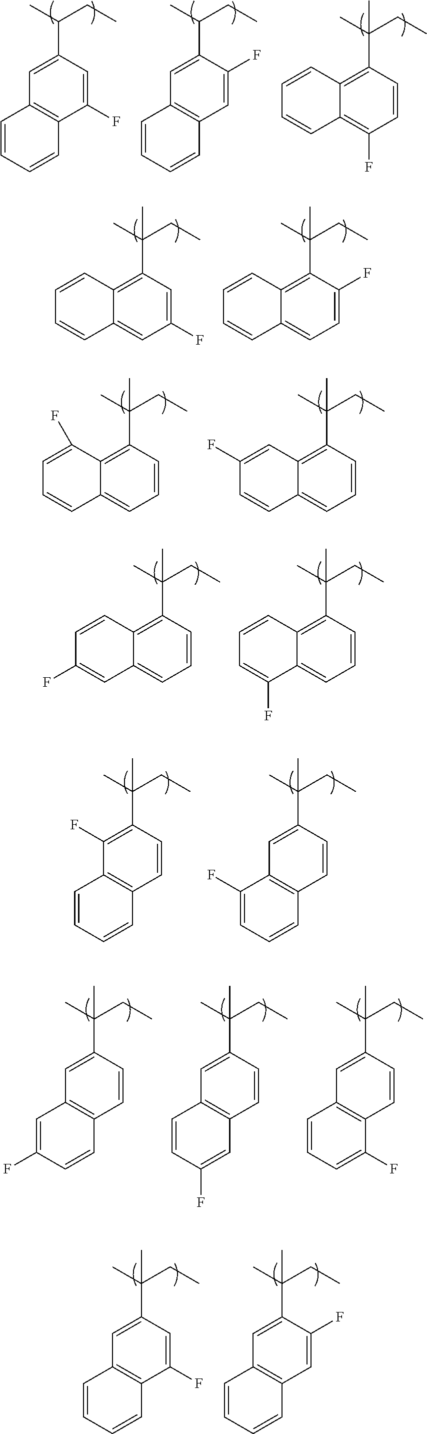

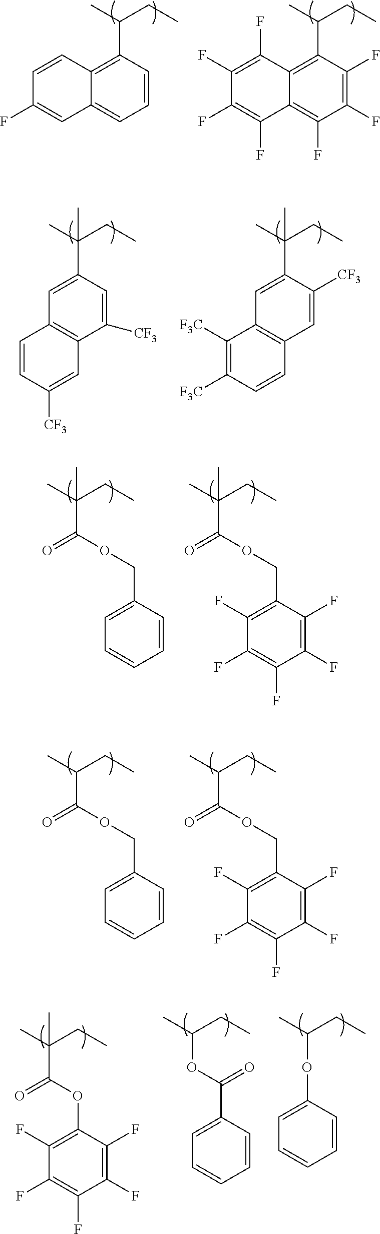

Hereinafter, the repeating unit represented by the formula (3) will be explained.

In the formula (3), Z represents an alkyl group having a number of carbon atoms of 1 to 20 or an alkenyl group having a number of carbon atoms of 2 to 20. A hydrogen atom contained in the group represented by Z may be substituted by a fluorine atom, and a methyl group, an ethyl group, a n-propyl group, a n-butyl group, a sec-butyl group, an isobutyl group, a n-hexyl group, a n-octyl group, a n-dodecyl group, a 2-ethylhexyl group, a cyclohexyl group, a trifluoromethyl group, a 2,2,2-trifluoroethyl group, a 2-(perfluorobutyl)ethyl group, a 2-(perfluorooctyl) ethyl group, a 2-(perfluorodecyl)ethyl group, a vinyl group and the like are mentioned, and a methyl group, a butyl group, a trifluoromethyl group or a trifluoroethyl group is preferable.

R^{2 1}, R^{2 2} and R^{2 3} are each independently a hydrogen atom, a fluorine atom or an alkyl group having a number of carbon atoms of 1 to 20, R^{2 1} is preferably a hydrogen atom or a methyl group, and R^{2 2} and R^{2 3} preferably represent a hydrogen atom or an branched alkylene bonding to Z to form a norbornene skeleton.

R^{h} represents a divalent organic group having a number of carbon atoms of 1 to 20, a group represented by —O— or a group represented by —C(═O)—. R^{h} is preferably a methylene group, a group represented by —O— or a group represented by —C(═O)—.

r represents an integer of 0 to 6. r is preferably an integer of 0 to 3.

Examples of monomers as the raw material of the repeating unit represented by the formula (3) include α-olefins such as ethylene, propylene, 1-butene, 1-pentene, 1-hexene, 1-octene, vinylcyclohexane and the like, norbornenes such as 2-norbornene, 5-butyl-2-norbornene, 5-octyl-2-norbornene, 5-perfluorooctyl-2-norbornene and the like, conjugated dienes such as 1,3-butadiene, 2-methyl-1,3-butadiene, 2,3-dimethyl-1,3-butadiene and the like, acrylates such as methyl acrylate, ethyl acrylate, n-propyl acrylate, isopropyl acrylate, n-butyl acrylate, isobutyl acrylate, sec-butyl acrylate, hexyl acrylate, octyl acrylate, 2-ethylhexyl acrylate, decyl acrylate, isobornyl acrylate, cyclohexyl acrylate, 2,2,2-trifluoroethyl acrylate, 2,2,3,3,3-pentafluoropropyl acrylate, 2-(perfluorobutyl) ethyl acrylate, 2-(perfluorohexyl)ethyl acrylate, 2-(perfluorooctyl)ethyl acrylate, 2-(perfluorodecyl) ethyl acrylate, 2-(perfluoro-3-methylbutyl)ethyl acrylate, 2-(perfluoro-5-methylhexyl)ethyl acrylate, 2-(perfluoro-7-methyloctyl)ethyl acrylate, 1H,1H,3H-tetrafluoropropyl acrylate, 1H,1H,5H-octafluoropentyl acrylate, 1H,1H,7H-dodecafluoroheptyl acrylate, 1H,1H,9H-hexadecafluorononyl acrylate, 1H-1-(trifluoromethyl)trifluoroethyl acrylate, 1H,1H,3H-hexafluorobutyl acrylate and the like, and methacrylates such as methyl methacrylate, ethyl methacrylate, n-propyl methacrylate, isopropyl methacrylate, n-butyl methacrylate, isobutyl methacrylate, sec-butyl methacrylate, hexyl methacrylate, octyl methacrylate, 2-ethylhexyl methacrylate, decyl methacrylate, isobornyl methacrylate, cyclohexyl methacrylate, 2,2,2-trifluoroethyl methacrylate, 2,2,3,3,3-pentafluoropropyl methacrylate, 2-(perfluorobutyl)ethyl methacrylate, 2-(perfluorohexyl)ethyl methacrylate, 2-(perfluorooctyl) ethyl methacrylate, 2-(perfluorodecyl)ethyl methacrylate, 2-(perfluoro-3-methylbutyl)ethyl methacrylate, 2-(perfluoro-5-methylhexyl)ethyl methacrylate, 2-(perfluoro-7-methyloctyl)ethyl methacrylate, 1H,1H,3H-tetrafluoropropyl methacrylate, 1H,1H,5H-octafluoropentyl methacrylate, 1H,1H,7H-dodecafluoroheptyl methacrylate, 1H,1H,9H-hexadecafluorononyl methacrylate, 1H-1-(trifluoromethyl) trifluoroethyl methacrylate, 1H,1H,3H-hexafluorobutyl methacrylate and the like.

Specific examples of the repeating unit represented by the formula (3) are shown below, but the present embodiment is not limited to them.

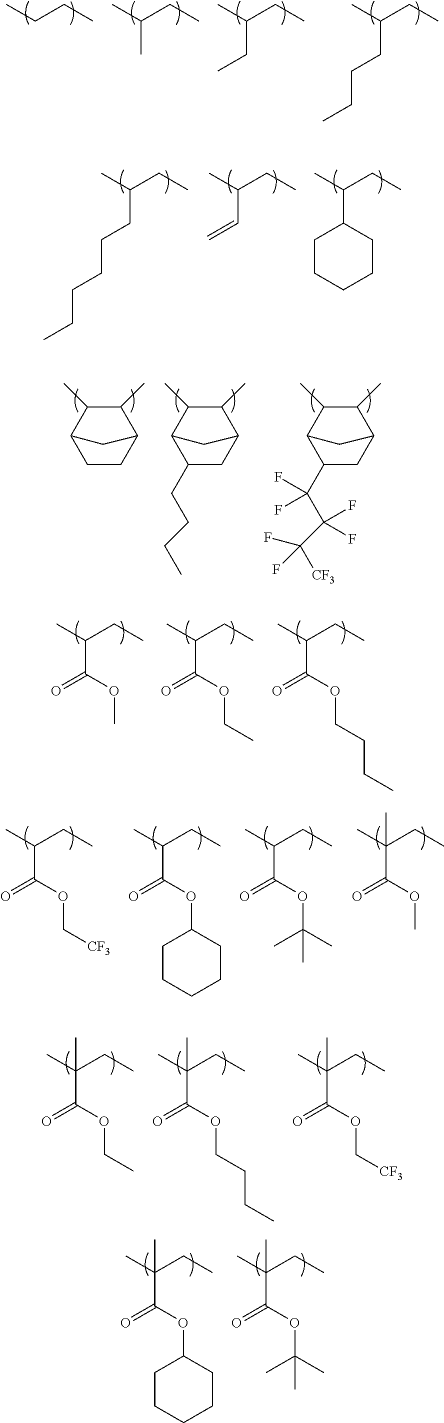

Hereinafter, the repeating unit represented by the formula (4) will be explained.

In the formula (4), R^{2 4} and R^{2 5} each independently represent a hydrogen atom or an alkyl group having a number of carbon atoms of 1 to 20, and a hydrogen atom or a methyl group is preferable.

Examples of monomers as the raw material of the repeating unit represented by the formula (4) include conjugated dienes such as 1,3-butadiene, 2-methyl-1,3-butadiene, 2,3-dimethyl-1,3-butadiene and the like.

Specific examples of the repeating unit represented by the formula (4) are shown below, but the present embodiment is not limited to them.

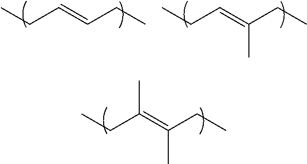

The above-described polymer compound has a polystyrene-equivalent weight-average molecular weight of preferably 3,000 to 1,000,000, more preferably 5,000 to 500,000, further preferably 9,000 to 300,000. The polymer compound may be any of linear, branched or cyclic.

Specific examples of the polymer compound contained in the photosensitive composition of the present invention are shown below, but the present embodiment is not limited to them.

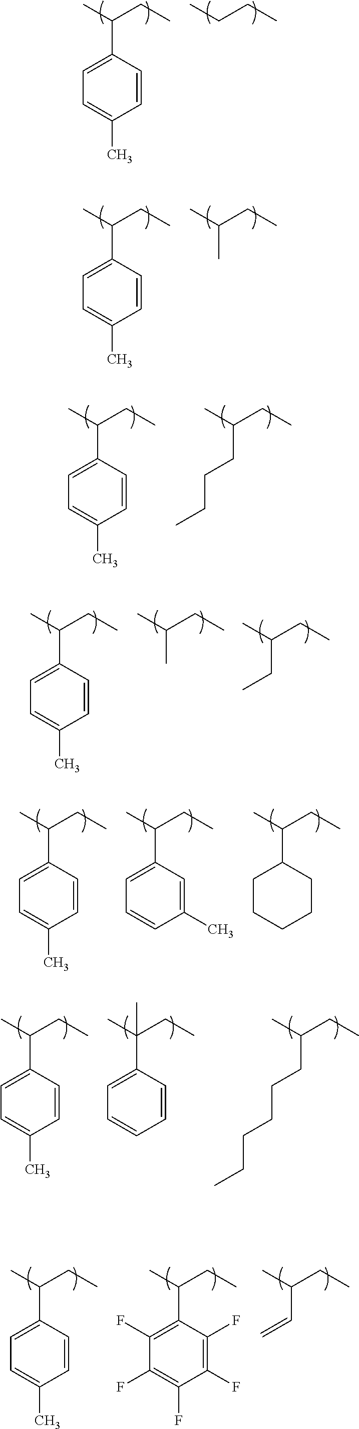

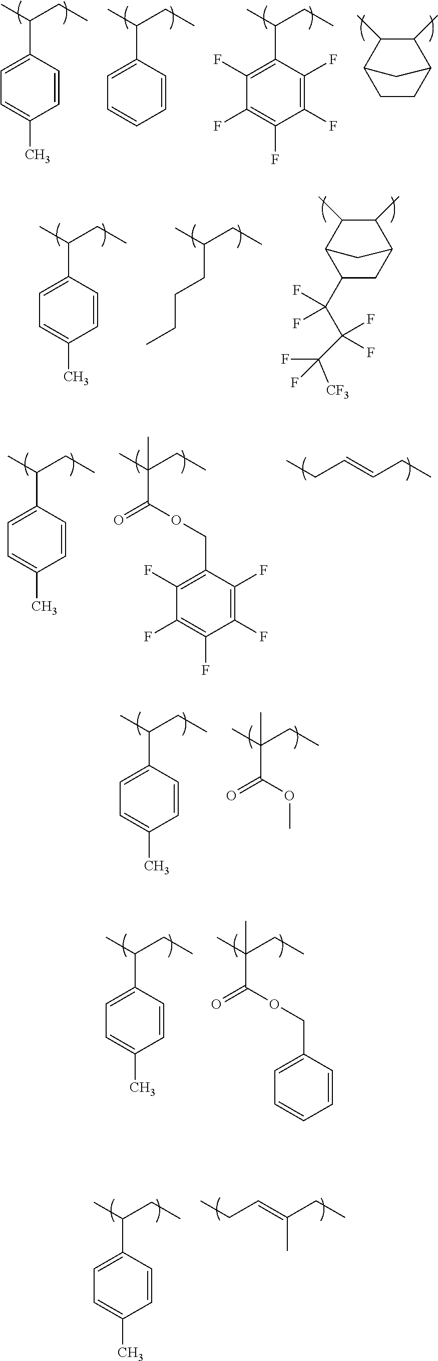

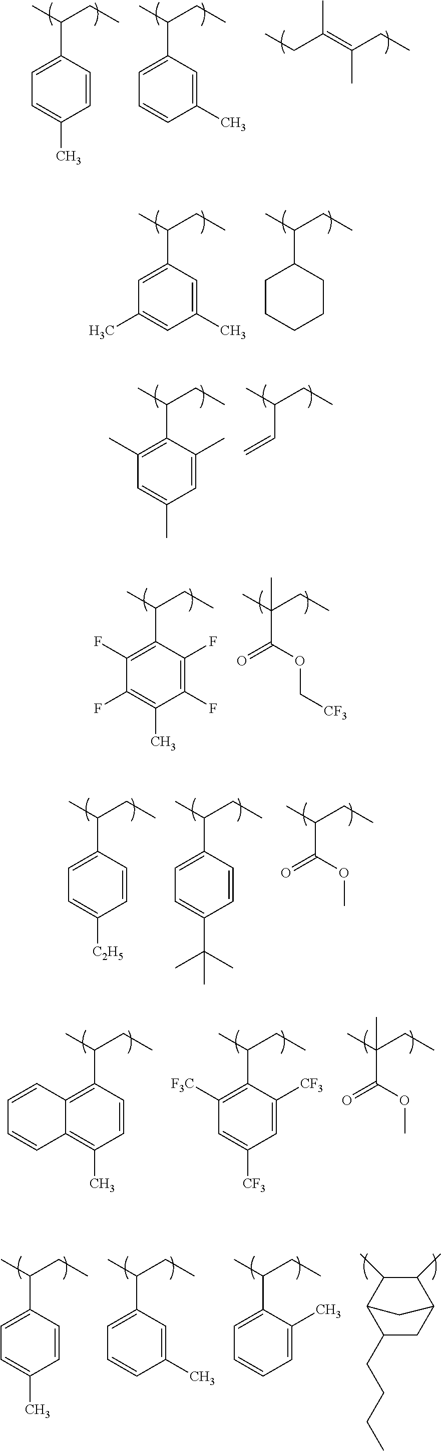

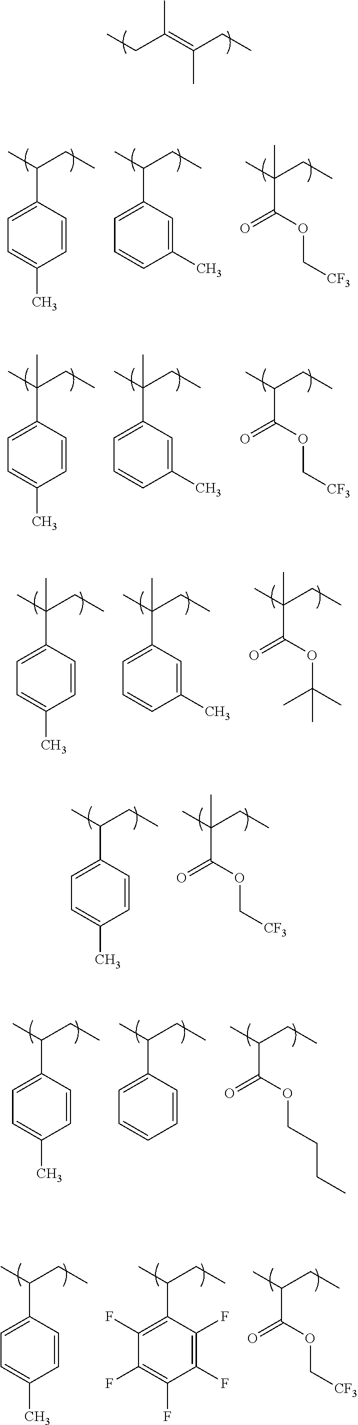

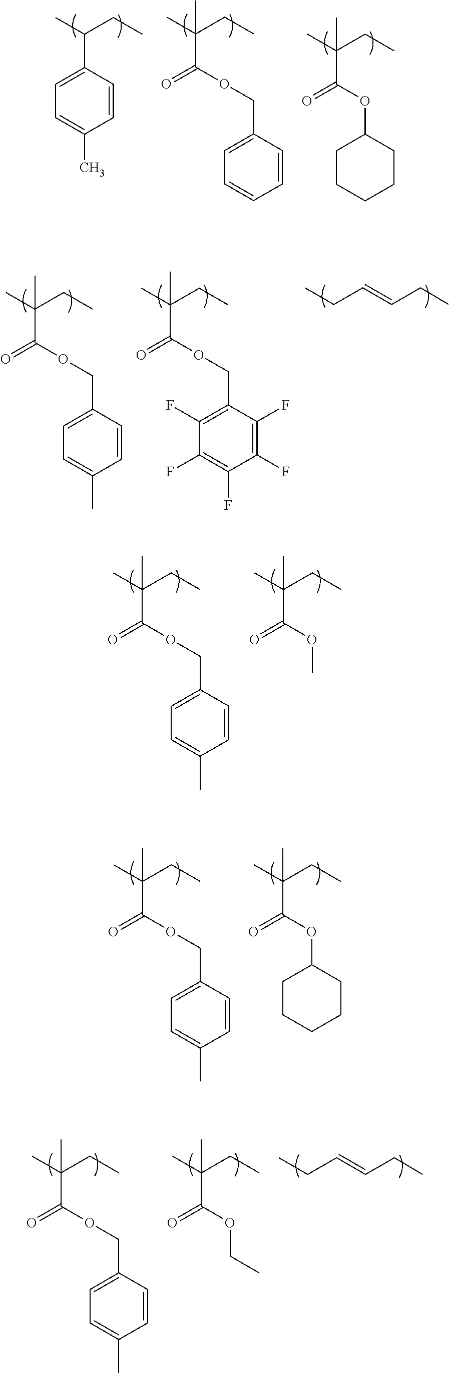

### (Production Method of Polymer Compound)

The polymer compound can be produced, for example, by a method of copolymerizing a monomer (polymerizable monomer) as the raw material of the repeating unit represented by the formula (1) and a monomer (polymerizable monomer) as at least one raw material selected from the group consisting of repeating units represented by at least one formula selected from the group consisting of the formula (2), the formula (3) and the formula (4), using a photopolymerization initiator, a thermal polymerization initiator, an anionic polymerization initiator or a metallocene catalyst.

The photopolymerization initiator used for production of a polymer compound includes, for example, carbonyl compounds such as acetophenone, 2,2-dimethoxy-2-phenylacetophenone, 2,2-diethoxyacetophenone, 4-isopropyl-2-hydroxy-2-methylpropiophenone, 2-hydroxy-2-methylpropiophenone, 4,4′-bis(diethylamino)benzophenone, benzophenone, methyl(o-benzoyl) benzoate, 1-phenyl-1,2-propanedione-2-(o-ethoxycarbonyl)oxime, 1-phenyl-1,2-propanedione-2-(o-benzoyl)oxime, benzoin, benzoin methyl ether, benzoin ethyl ether, benzoin isopropyl ether, benzoin isobutyl ether, benzoin octyl ether, benzyl, benzyl dimethyl ketal, benzyl diethyl ketal, diacetyl and the like, anthraquinone or thioxanthone derivatives such as methylanthraquinone, chloroanthraquinone, chlorothioxanthone, 2-methylthioxanthone, 2-isopropylthioxanthone and the like, and sulfur compounds such as diphenyl disulfide, dithiocarbamate and the like.

The thermal polymerization initiator used for production of a polymer compound may be any one as long as it serves as an initiator for radical polymerization, and includes, for example, azo compounds such as 2,2′-azobisisobutyronitrile, 2,2′-azobisisovaleronitrile, 2,2′-azobis(2,4-dimethylvaleronitrile), 4,4′-azobis(4-cyano valeric acid), 1,1′-azobis(cyclohexanecarbonitrile), 2,2′-azobis(2-methylpropane), 2,2′-azobis(2-methylpropionamidine)dihydrochloride and the like, ketone peroxides such as methyl ethyl ketone peroxide, methyl isobutyl ketone peroxide, cyclohexanone peroxide, acetylacetone peroxide and the like, diacyl peroxides such as isobutyl peroxide, benzoyl peroxide, 2,4-dichlorobenzoyl peroxide, o-methylbenzoyl peroxide, lauroyl peroxide, p-chlorobenzoyl peroxide and the like, hydroperoxides such as 2,4,4-trimethylpentyl-2-hydroperoxide, diisopropylbenzene peroxide, cumene hydroperoxide, tert-butyl peroxide and the like, dialkyl peroxides such as dicumyl peroxide, tert-butylcumyl peroxide, di-tert-butyl peroxide, tris(tert-butylperoxy)triazine and the like, peroxy ketals such as 1,1-di-tert-butylperoxycyclohexane, 2,2-di(tert-butylperoxy)butane and the like, alkyl peresters such as tert-butylperoxy pivalate, tert-butylperoxy-2-ethylhexanoate, tert-butylperoxyisobutyrate, di-tert-butylperoxyhexahydro terephthalate, di-tert-butylperoxy azelate, tert-butylperoxy-3,5,5-trimethylhexanoate, tert-butylperoxy acetate, tert-butylperoxy benzoate, di-tert-butylperoxytrimethyl adipate and the like, and percarbonates such as diisopropylperoxy dicarbonate, di-sec-butylperoxy dicarbonate, tert-butylperoxyisopropyl carbonate and the like.

The anionic polymerization initiator used for production of a polymer compound includes, for example, alkyllithiums such as n-butyllithium, sec-butyllithium and the like.

The metallocene olefin polymerization catalyst used for production of a polymer compound includes, for example, metallocene olefin polymerization catalysts constituted of a group 4 metallocene complex selected from cyclopentadietnyltitanium trichloride, titanocene dichloride, ethylenebisindacenotitanocene dichloride, ethylenebisindacenozirconocene dichloride and the like and a group 3 cocatalyst selected from methylallumoxane, triphenylmethyliumtetrakis(pentafluorophenyl) borate and the like.

### <Compound Having at Least Two Zzide Groups>

The photosensitive composition of the present invention contains a compound having at least two azide groups.

The compound having at least two azide groups may be a low molecular weight compound or a polymer compound.

The compound having at least two azide groups is preferably a low molecular weight compound, and includes, for example, compounds represented by the following formula (5).

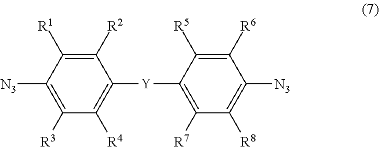

In the formula (7),

R¹ to R⁸ each independently represent a hydrogen atom, a fluorine atom, an alkyl group having a number of carbon atoms of 1 to 5, an alkoxy group having a number of carbon atoms of 1 to 5 or a group represented by SO₃M, wherein M represents a hydrogen atom, an alkali metal atom, an alkyl group having a number of carbon atoms of 1 to 10 or NR^{A}R^{B}, and R^{A} and R^{B} each independently represent a hydrogen atom, an alkyl group having a number of carbon atoms of 1 to 10, a hydroxyalkyl group having a number of carbon atoms of 1 to 10, an alkoxyalkyl group having a number of carbon atoms of 1 to 10 or a hydroxyalkoxyalkyl group having a number of carbon atoms of 1 to 10.

Y represents a single bond, a group represented by —C(═O)—, a group represented by —S—, an alkylene group having a number of carbon atoms of 1 to 8 or a divalent group represented by any one of the following formulae (7-1) to (7-4), wherein R⁹ is a hydrogen atom or an alkyl group having a number of carbon atoms of 1 to 10.

In the formula (7), R¹ to R⁸ are each independently preferably a hydrogen atom, a fluorine atom or an alkyl group having a number of carbon atoms of 1 to 5.

In the formula (7-4), R⁹ is preferably a hydrogen atom, a methyl group or an ethyl group.

Y is preferably a group represented by —C(═O)—, or a divalent group represented by the above-described formula (7-1) or the above-described formula (7-4).

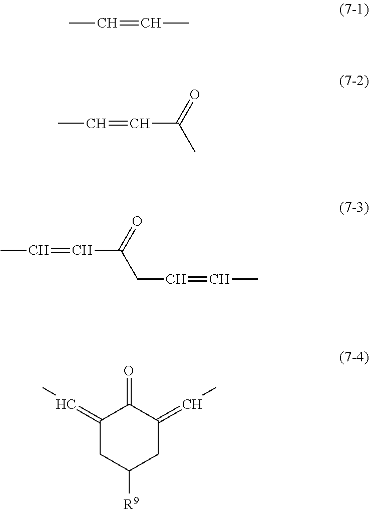

Specific examples of the compound having at least two azide groups are 4,4′-diazidechalcone, 4,4′-diazidedibenzalacetone, 2,6-bis(4′-azidebenzal)cyclohexanone, 2,6-bis(4′-azidebenzal)-4-methyl-cyclohexanone, 2,6-bis(4′-azidebenzal)-4-ethylcyclohexanone, sodium 4,4′-diazidestilbene-2,2′-disulfonate, 4,4′-diazidediphenyl sulfide, 4,4′-diazidebenzophenone, 4,4′-diazidebiphenyl, 2,7-diazidefluorene, 4,4′-diazidephenylmethane, 1,2-diazideethane, 1,3-diazidepropane, 1,4-diazidebutane and 1,5-diazidepentane.

The compound having at least two azide groups includes also compounds described below.

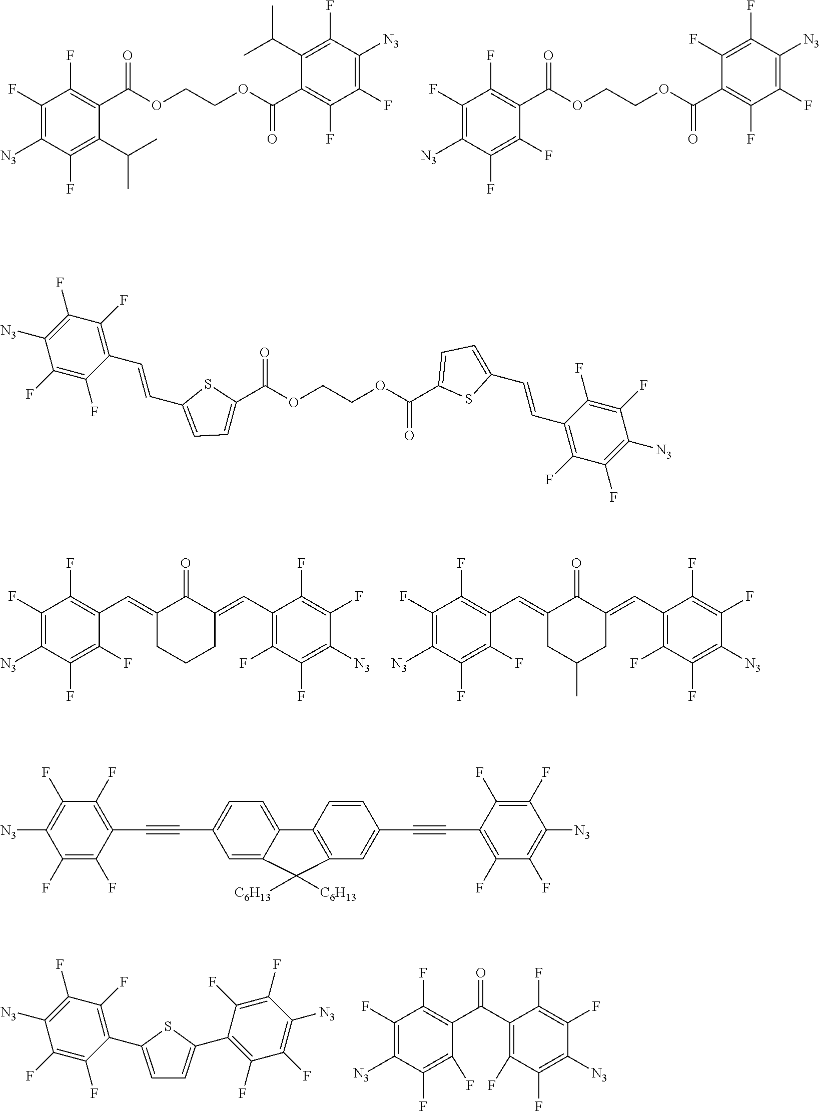

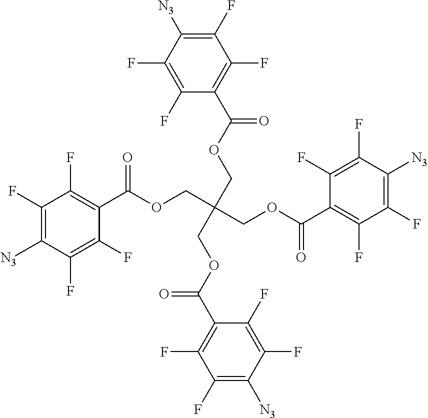 [SMILES: [N-]=[N+]=Nc1c(F)c(F)c(C(=O)OCC(COC(=O)c2c(F)c(F)c(N=[N+]=[N-])c(F)c2F)(COC(=O)c2c(F)c(F)c(N=[N+]=[N-])c(F)c2F)COC(=O)c2c(F)c(F)c(N=[N+]=[N-])c(F)c2F)c(F)c1F]

The compounds having at least two azide groups may be used each singly or in combination of two or more kinds thereof.

In the photosensitive composition of the present invention, the compound having at least two azide groups is contained in an amount of preferably 0.1 to 10% by mass, more preferably 0.1 to 10% by mass, further preferably 0.5 to 10% by mass, particularly preferably 0.75 to 5% by mass, most preferably 1 to 3% by mass with respect to the polymer compound composed of the repeating unit represented by the formula (1) and a repeating unit represented by at least one formula selected from the group consisting of the formula (2), the formula (3) and the formula (4).

### <Ink>

The embodiment of the present invention may be an ink containing a photosensitive composition and an organic solvent (in the present specification, referred to as application solution in some cases).

For example, it may also be an ink containing a polymer compound composed of the repeating unit represented by the formula (1) and a repeating unit represented by at least one formula selected from the group consisting of the formula (2), the formula (3) and the formula (4), the above-described compound having at least two azide groups, and an organic solvent.

In the ink of the present invention, the preferable content of the compound having at least two azide groups with respect to the polymer compound composed of the repeating unit represented by the formula (1) and a repeating unit represented by at least one formula selected from the group consisting of the formula (2), the formula (3) and the formula (4) is the same as the preferable content in the above-described photosensitive composition.

The organic solvent includes ether solvents such as tetrahydrofuran, diethyl ether and the like, aliphatic hydrocarbon solvents such as hexane and the like, alicyclic hydrocarbon solvents such as cyclohexane and the like, unsaturated hydrocarbon solvents such as pentene and the like, aromatic hydrocarbon solvents such as xylene and the like, ketone solvents such as cyclopentanone, 2-heptanone, acetone and the like, acetate solvents such as propylene glycol monomethyl ether acetate, butyl acetate and the like, alcohol solvents such as 2-ethoxyethanol and the like, halide solvents such as chloroform and the like, and mixed solvents thereof. Organic solvents having a boiling point of 100° C. to 200° C. at normal pressure are preferable from the standpoint of easy formation of a uniform applied film, and specific examples thereof include 2-heptanone, propylene glycol monomethyl ether acetate (PGMEA), cyclopentanone, 2-ethoxyethanol and the like.

When the ink of the present invention is used for fabrication of a hardened film described later, the amount of an organic solvent contained in the ink is preferably 30% by mass to 95% by mass when the total mass of the ink is taken as 100% by mass.

### <Hardened Film>

The embodiment of the present invention may also be a film obtained by hardening the photosensitive composition of the present invention described above.

The hardened film can be obtained as a film on which a pattern has been formed since the photosensitive composition of the present invention is excellent in a patterning property.

The thickness of the hardened film of the present invention is preferably 1 nm to 100 μm, more preferably 10 nm to 10 μm, further preferably 100 nm to 5 μm.

The hardened film of the present invention can effectively improve the carrier mobility of an organic thin-film transistor by being adopted in a gate insulation layer of the organic thin-film transistor.

The photosensitive composition of the present invention can be suitably used as the material of an interlayer insulator, a protective layer (overcoat layer) and an underlying layer (undercoat layer) of an organic thin-film transistor, since an insulation property, a sealing property, an adhesion property and a solvent resistance thereof are excellent when hardened.

### <Production Method of Hardened Film>

The production method of a hardened film of the present invention preferably contains the following steps (1) to (5).

(1) a step of applying the ink on an object to obtain a film (application step)

(2) a step of removing an organic solvent from the resultant film (prebake step)

(3) a step of exposing the organic solvent-removed film (exposure step)

(4) a step of contacting the exposed film and a developing solution to execute development (development step)

(5) a step of heating the developed film (post bake step)

When patterning is not required, the step (4) may not be carried out.

The steps will be explained in series below.

(1) (Application Step)

The ink applying method includes a spin coating method, a die coating method, a screen printing method, an inkjet method and the like. By applying an ink on an object, a film can be formed.

The object used in the application step includes, for example, a silicon wafer, a ceramic substrate or an organic substrate. The ceramic substrate includes, for example, glass substrates such as soda glass, alkali-free glass, borosilicate glass, quartz glass and the like; an alumina substrate, an aluminum nitride substrate or a silicon carbide substrate. The organic substrate includes, for example, an epoxy substrate, a polyether imide resin substrate, a polyether ketone resin substrate, a polysulfone type resin substrate, a polyimide film or a polyester film.

### (2) (Prebake Step)

In the step (2), an organic solvent is removed from the above-described film by depressurization (vacuum) and/or heating, and the like, to form a dried film. The heating conditions may be appropriately selected depending on the kind, the content and the like of a polymer compound in an ink, and preferably selected from among a temperature of 40° C. to 130° C. and a time of 30 to 600 seconds, more preferably selected from among a temperature of 50° C. to 110° C. and a time of 30 to 600 seconds, further preferably selected from among a temperature of 80° C. to lower than 100° C. and a time of 30 to 600 seconds.

In these heating treatments, known heating means such as a hot plate, an oven, an infrared heater and the like can be used.

When the temperature and the time are within the above-described ranges, there is a tendency that in carrying out the step (4) described later, the adhesion property of a pattern is better, and the residue associated with dissolution removal can also be reduced.

### (3) (Exposure Step)

In the step (3), a film is irradiated with an active ray of prescribed pattern.

For example, an electronic circuit pattern drawn on a mask or reticle is transferred to the dried film after prebaking using an exposure apparatus.

As the exposure apparatus, exposure machines of various modes such as a mirror projection aligner, a stepper, a scanner, a proximity, a contact, a micro lens array, a lens scanner, laser exposure and the like can be used. Further, exposure can also be performed using a so-called super resolution technology. The super resolution technology includes multiple exposure performing exposure multiple times, a method using a phase shift mask, an annular illumination method and the like.

As the active ray light source included in the exposure apparatus, a low pressure mercury lamp, a high pressure mercury lamp, an extra high pressure mercury lamp, a chemical lamp, a light emitting diode (LED) light source, an excimer laser generator and the like can be used, and an active ray having a wavelength of 300 nm or more and 450 nm or less such as i line (365 nm), h line (405 nm), g line (436 nm) and the like can be preferably used. Further, it is also possible to adjust irradiation light through a spectral filter such as a long wavelength cut filter, a short wavelength cut filter and a band pass filter, if necessary. The exposure dose is preferably 1 to 5000 mJ/cm², more preferably 10 to 2000 mJ/cm², further preferably 50 to 500 mJ/cm².

If oxygen or the like is present around a film in irradiating with an active ray, the cross-linking reaction may be disturbed, hence, it is preferable that an inert gas such as nitrogen, argon or the like is supplied around the film and the film is irradiated with an active ray under an inert atmosphere.

Further, the film can also be irradiated with an active ray while heating the film. For example, temperatures in the range of 50 to 150° C. can be applied. The range of 50° C. to lower than 100° C. is more preferable.

If necessary, the bake step (2) may be carried out after the exposure step.

### (4) (Development Step)

In the step (4), the exposed dried film and a developing solution are brought into contact, and a photosensitized area or a non-photosensitized area is dissolved and removed, to attain development.

The developing method may be any of a liquid deposition method (paddle method), a shower method, a dipping method and the like.

After the development step, a rinse step can also be carried out. In the rinse step, a substrate after development is washed with pure water, isopropyl alcohol and the like, to remove the developing solution adhered or remove the development residue. As the rinse method, known methods can be used. For example, shower rinse, dip rinse and the like are listed.

Usually, a solvent which dissolves a polymer compound contained in a photosensitive composition is selected as a developing solution. The dissolution contrast which is a difference in the dissolution speed against a developing solution between a part irradiated with an active ray (hereinafter, referred to as exposed part) and a part not irradiated with an active ray (hereinafter, referred to as unexposed part) is important in development. By using a developing solution which increases the dissolution contrast, it is possible to form a fine pattern with low dose of an active ray.

The dissolution contrast can be adjusted by changing the mass ratio of a good solvent and a poor solvent of a polymer compound contained in a developing solution.

The above-described good solvent includes ketone type solvents such as acetone, methyl ethyl ketone, 2-heptanone and the like, ester solvent such as ethyl acetate, butyl acetate, ethyl lactate, propylene glycol monomethyl ether acetate, γ-butyrolactone and the like, amide solvents such as N,N-dimethylformamide, N,N-dimethylacetamide, N-methyl-2-pyrrolidone and the like, and ether solvents such as tetrahydrofuran, tetrahydropyran and the like.

The above-described poor solvent includes methanol, ethanol, 1-propanol, 2-propanol, 1-butanol, 2-butanol, 1-pentanol, 2-pentanol, 3-pentanol and the like.

The mass ratio of good solvent/poor solvent of a developing solution is preferably 100/0 to 5/95, more preferably 100/0 to 10/90, further preferably 100/0 to 20/80, still preferably 100/0 to 30/70.

The developing time is usually 5 seconds to 300 seconds. The developing time is preferably 20 seconds to 250 seconds, more preferably, 30 seconds to 200 seconds, further preferably 40 seconds to 150 seconds. When the developing time is short, the residue may remain, while when long, a pattern may be peeled.

Since the dissolution contrast varies depending on the monomer composition and the molecular weight of a polymer compound and bake conditions (temperature, time) after exposure which is executed if necessary and the like, the developing solution composition, the developing time and the developing temperature are appropriately regulated so as to be optimized.

### (5) (Post Bake Step)

In the step (5), after the above-described development step, a film is dried by conducting a heating step (post bake step) on the resultant film, to form an insulation layer which is a layer composed of a hardened substance of a photosensitive resin composition. The heating conditions may be appropriately selected and preferably selected from among a temperature of 40° C. to 150° C. and a time of 1 minute to 180 minutes, more preferably selected from among a temperature of 50° C. to 120° C. and a time of 3 minutes to 120 minutes, further preferably selected from among a temperature of 60° C. to 100° C. and a time of 5 minutes to 60 minutes, particularly preferably selected from among a temperature of 60° C. to lower than 100° C. and a time of 5 minutes to 60 minutes. For these heating treatments, known heating means such as a hot plate, an oven, an infrared heater and the like can be used.

The hardening speed of a film can be promoted by subjecting a substrate having a pattern formed to whole surface re-exposure (post exposure) with an active ray before performing the post bake. When the post exposure step is included, the dose is preferably 100 to 3000 mJ/cm², more preferably 100 to 500 mJ/ cm².

The hardened film obtained by the photosensitive resin composition of the present invention can also be used as a dry etching resist or a wet etching resist. When used as a dry etching resist, dry etching treatments such as asking, plasma etching, ozone etching and the like can be carried out as the etching treatment.

### <Evaluation Method of Patterning Property>

The patterning property of a photosensitive composition can be evaluated by conducting the following measurement in a step of producing a hardened film using a photosensitive composition.

An application step, a prebake step and an exposure step are carried out, and the thickness of a film at an exposed part is measured using a stylus type film thickness meter, and set as dl.

Further, an application step, a prebake step, an exposure step and a development step are carried out, and the thicknesses of a film at an unexposed part and an exposed part are measured using a stylus type film thickness meter, and set as d2 and d3, respectively.

The value of (d2/d1)×100 is defined as the residual film ratio of an unexposed part after a development step.

The value of (d3/d1)×100 is defined as the residual film ratio of an exposed part after a development step.

The good patterning property means that the residual film ratio of an unexposed part is low and the residual film ratio of an exposed part is high.

Since d1, d2 and d3 are measured at different points, respectively, the residual film ratio may slightly exceed 100% when the film is not dissolved in a developing solution at all, however, in this case, the substantial residual film ratio can be regarded as 100%.

### <Electronic Device>

An electronic device containing the above-described hardened film will be explained. Since the photosensitive composition of the present embodiment can be hardened at low temperature, the hardened film using the photosensitive composition can be used for various electronic devices such as an organic thin-film transistor, an organic LED, a sensor and the like.

As the electronic device containing the hardened film using the composition, an organic thin-film transistor is suitable. It is suitable for the organic thin-film transistor to contain the hardened film as a gate insulation layer of the organic thin-film transistor.

The organic thin-film transistor may have, for example, a hardened film obtained by hardening the photosensitive composition of the present invention as a gate insulation layer, and further, may have the hardened film as an interlayer insulator, a protective layer (overcoat layer) and an underlying layer (undercoat layer).

Hereinafter, the organic thin-film transistor containing the hardened film of the present invention will be explained.

### <Organic Thin-Film Transistor>

The organic thin-film transistor of the present invention is an organic thin-film transistor having an insulation layer, a source electrode, a drain electrode, a gate electrode and an organic semiconductor layer, and forming the insulation layer using the above-described photosensitive composition of the present invention or its hardened film.

### <Insulation Layer>

The insulation layer included in the organic thin-film transistor of the present invention is composed the above-described photosensitive composition or its hardened film. The insulation layer included in the organic thin-film transistor of the present invention includes a gate insulation layer, a protective layer, an underlying layer, an interlayer insulator and the like. The protective layer is provided on the organic thin-film transistor, and by this, the organic thin-film transistor is isolated from the atmospheric air, and decrease in characteristics of the organic thin-film transistor can be suppressed. When a display device or the like to be driven is formed on the organic thin-film transistor, an influence on the organic thin-film transistor in its formation step can also be reduced by the protective layer. The underlying layer is provided under the organic thin-film transistor, and can flatten the irregularity of a substrate and can improve the adhesion property between the substrate and the organic thin-film transistor. The interlayer insulator is provided above the protective layer, and a display device or the like to be formed on the organic thin-film transistor is formed above the interlayer insulator. The protective layer can also serve as the interlayer insulator.

### <Source Electrode, Drain Electrode and Gate Electrode>

The material constituting a source electrode, the material constituting a drain electrode and the material constituting a gate electrode include chromium, gold, silver, aluminum and the like.

### <Organic Semiconductor Layer>

The organic semiconductor layer included in the organic thin-film transistor is a layer containing an organic semiconductor compound.

As the organic semiconductor compound as the material of an organic semiconductor layer, n conjugated polymers are widely used and, for example, polypyrroles, polythiophenes, polyanilines, polyallylamines, fluorenes, polycarbazoles, polyindoles, poly(p-phenylenevinylene)s and the like can be used.

As the organic semiconductor compound as the material of an organic semiconductor layer, low molecular weight compounds having solubility in an organic solvent can also be used. Such low molecular weight compounds include, for example, polycyclic aromatic derivatives such as pentacene and the like; phthalocyanine derivatives, perylene derivatives, tetrathiafulvalene derivatives, tetracyanoquinodimethane derivatives, fullerenes, carbon nanotubes and the like. Examples of such low molecular weight compounds include, specifically, 6,13-bistriisopropylsilylethynylpentacene, 1,4,8, 11-tetramethyl-6, 13-triethylsilylethynylpentacene, 2,7-dioctyl[1]benzothieno[3,2-b][1]benzothiophene, 2,9-octyldinaphtho[2,3-b:2′,3′-f]thieno[3,2-b]thiophene, 2,8-difluoro-5,11-bis(triethylsilylethynyl)anthradithiophene and the like.

The organic semiconductor compound includes, for example, compounds having structures represented by the following formulas.

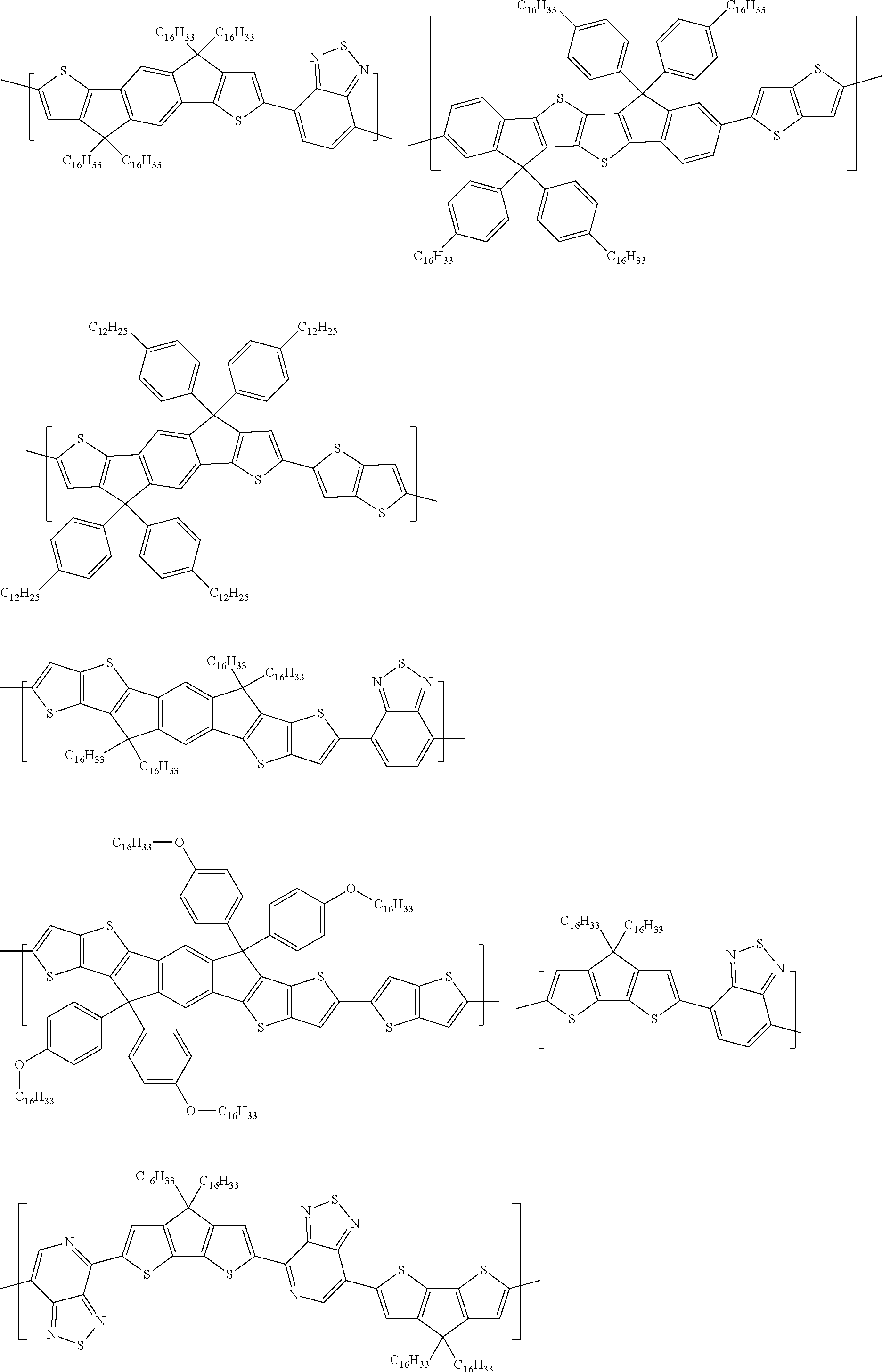

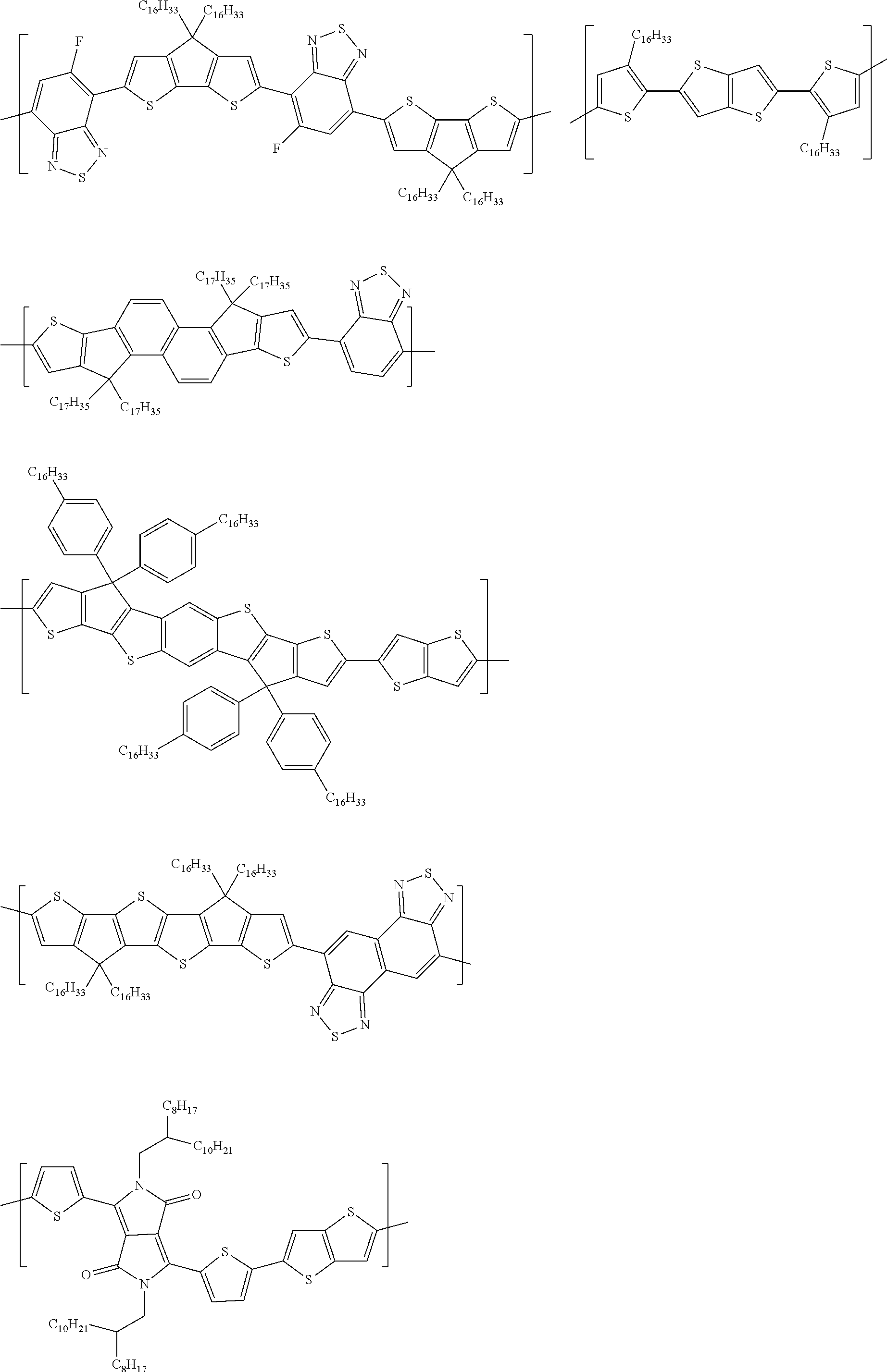

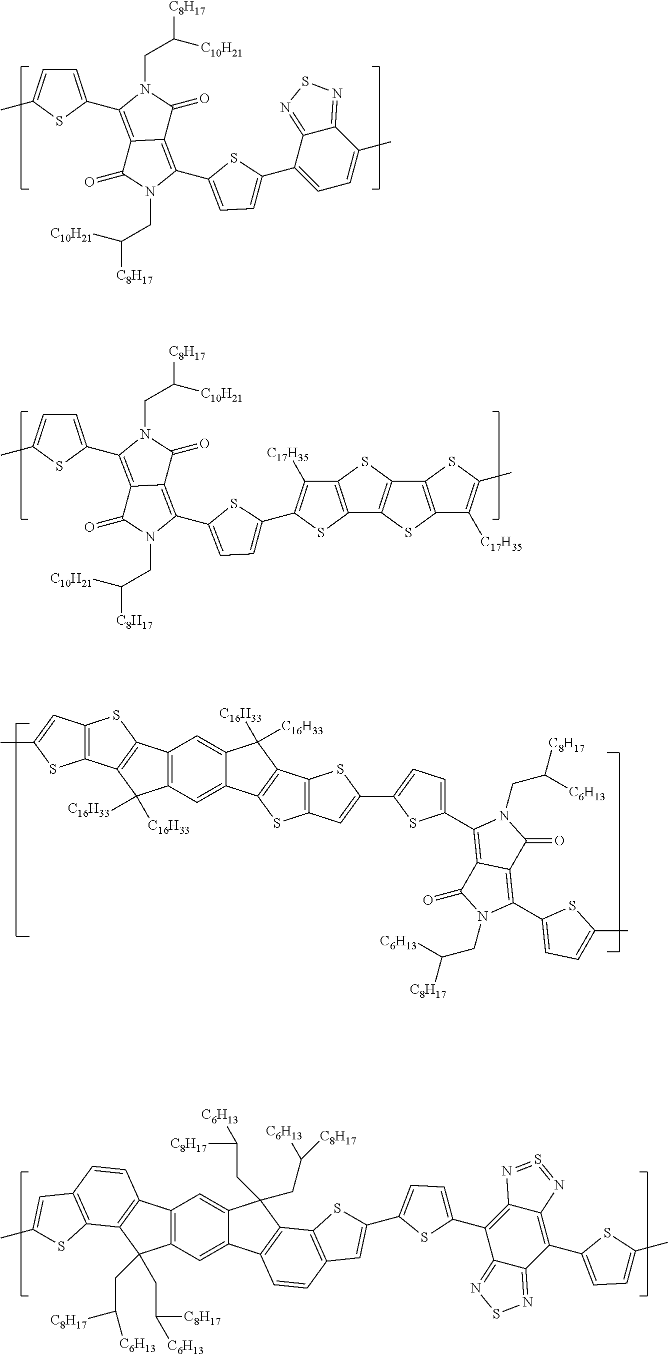

### <Other Layers>

The organic thin-film transistor may have a substrate and the like, in addition to an insulation layer, a source electrode, a drain electrode, a gate electrode and an organic semiconductor layer.

Usually, the film transistor has a substrate as the lowest layer. The substrate includes a plastic film, a glass plate, a silicon plate and the like.

The photosensitive composition of the present invention or its hardened film can be used as an interlayer insulator, a protective layer or an underlying layer, however, other substances may also be used as an interlayer insulator, a protective layer or an underlying layer. The compound constituting an interlayer insulator, a protective layer and an underlying layer may be an organic compound or an inorganic compound. The compound constituting an interlayer insulator, a protective layer and an underlying layer includes an UV curable resin, a thermosetting resin, SiONₓ (x>0) and the like.

### <Structure of Organic Thin-Film Transistor>

The organic thin-film transistor of the present invention may have a bottom gate type structure or a top gate type structure.

The organic thin-film transistor preferably has a top gate type structure in which a substrate, an organic semiconductor layer and a gate insulation layer are disposed in this order.

The organic thin-film transistor having a bottom gate type structure includes a bottom gate bottom contact type organic thin-film transistor and a bottom gate top contact type organic thin-film transistor.

The organic thin-film transistor having a top gate type structure includes a top gate bottom contact type organic thin-film transistor and a top gate top contact type organic thin-film transistor.

### (Bottom Gate Top Contact Type Organic Thin-Film Transistor)

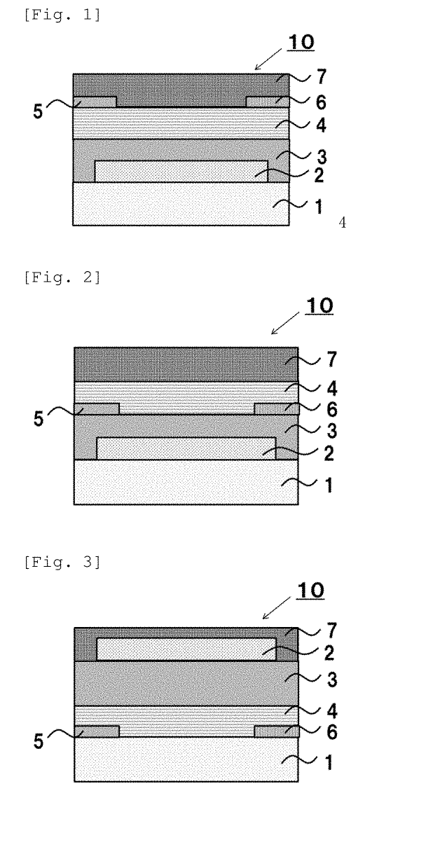

FIG. 1 is a schematic cross-sectional view showing the structure of a bottom gate top contact type organic thin-film transistor as one embodiment of the present invention. This organic thin-film transistor 10 has a substrate 1, a gate electrode 2 provided so as to be contacted to the main surface of the substrate 1, a gate insulation layer 3 provided on the substrate 1 so as to cover the gate electrode 2, an organic semiconductor layer 4 which is contacted adjacent to the gate insulation layer 3 and provided so as to cover directly above the gate electrode 2, a source electrode 5 and a drain electrode 6 which are contacted to the organic semiconductor layer 4 and provided so as to be separated from each other so that the channel region overlaps the gate electrode 2 when viewed in the thickness direction of the substrate 1 (in a planar view), and a protective layer 7 provided so as to cover the organic semiconductor layer 4.

In the bottom gate top contact type organic thin-film transistor, a gate insulation layer different from the gate insulation layer 3 may be further provided between the gate insulation layer 3 and the gate electrode 2.

In the bottom gate top contact type organic thin-film transistor, an underlying layer covering the substrate 1 may be further provided.

### (Bottom Gate Bottom Contact Type Organic Thin-Film Transistor)

FIG. 2 is a schematic cross-sectional view showing the structure of the bottom gate bottom contact type organic thin-film transistor as one embodiment of the present invention. This organic thin-film transistor 10 has a substrate 1, a gate electrode 2 provided so as to be contacted to the main surface of the substrate 1, a gate insulation layer 3 provided on the substrate 1 so as to cover the gate electrode 2, a source electrode 5 and a drain electrode 6 which are contacted to the gate insulation layer 3 and provided so as to be separated from each other so that the channel region overlaps the gate electrode 2 when viewed in the thickness direction of the substrate 1 (in a planar view), an organic semiconductor layer 4 which is contacted to the source electrode 5 and the drain electrode 6 and contacted adjacent to the gate insulation layer 3 and provided so as to cover directly above the gate electrode 2, and a protective layer 7 provided so as to cover the organic semiconductor layer 4.

In the bottom gate bottom contact type organic thin-film transistor, a gate insulation layer different from the gate insulation layer 3 may be further provided between the gate insulation layer 3 and the gate electrode 4.

In the bottom gate bottom contact type organic thin-film transistor, an underlying layer covering the substrate 1 may be further provided.

### (Top Gate Bottom Contact Type Organic Thin-Film Transistor)

FIG. 3 is a schematic cross-sectional view showing the structure of the top gate bottom contact type organic thin-film transistor as one embodiment of the present invention. This organic thin-film transistor 10 has a substrate 1; a source electrode 5 and a drain electrode 6 which are contacted to the substrate 1 and provided so as to be separated from each other so that the channel region overlaps the gate electrode 2 when viewed in the thickness direction of the substrate 1 (in a planar view), an organic semiconductor layer 4 which is contacted to the source electrode 5, the drain electrode 6 and the substrate and provided so as to cover directly below the gate electrode 2, a gate insulation layer 3 adjacent to the organic semiconductor layer 4, a gate electrode 2 provided so as to be contacted to the gate insulation layer 3, and a protective layer 7 so as to cover the gate electrode 2.

In the top gate bottom contact type organic thin-film transistor, a gate insulation layer different from the gate insulation layer 3 may be further provided between the gate insulation layer 3 and the gate electrode.

In the top gate bottom contact type organic thin-film transistor, an underlying layer covering the substrate 1 may be further provided.

### (Top Gate Top Contact Type Organic Thin-Film Transistor)

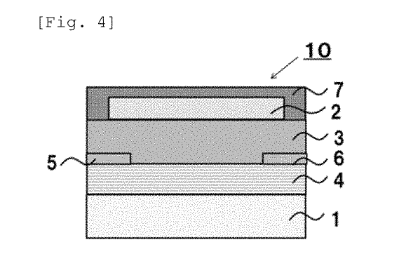

FIG. 4 is a schematic cross-sectional view showing the structure of the top gate top contact type organic thin-film transistor as one embodiment of the present invention. This organic thin-film transistor 10 has a substrate 1, an organic semiconductor layer 4 provided so as to be contacted to the main surface of the substrate 1, a source electrode 5 and a drain electrode 6 which are contacted to the organic semiconductor layer 4 and provided so as to be separated from each other so that the channel region overlaps the gate electrode 2 when viewed in the thickness direction of the substrate 1 (in a planar view), a gate insulation layer 3 which is contacted to the source electrode 5, the drain electrode 6 and the organic semiconductor layer 4 and provided so as to cover directly below the gate electrode 2, a gate electrode 2 provided so as to be contacted to the gate insulation layer 3, and a protective layer 7 so as to cover the gate electrode 2.

In the top gate top contact type organic thin-film transistor, a gate insulation layer different from the gate insulation layer 3 may be further provided between the gate insulation layer 3 and the gate electrode.

In the top gate top contact type organic thin-film transistor, an underlying layer covering the substrate 1 may be further provided.

In the organic thin-film transistor of the present invention, a layer containing at least one selected from the group consisting of low molecular weight compounds having electron transportability, low molecular weight compounds having hole transportability, alkali metals, alkaline earth metals, rare earth metals, complexes of these metals with organic compounds, halogens such as iodine, bromine, chlorine, iodine chloride and the like, sulfur oxide compounds such as sulfuric acid, sulfuric anhydride, sulfur dioxide, sulfate salt and the like, nitrogen oxide compounds such as nitric acid, nitrogen dioxide, nitrate salt and the like, halogenated compounds such as perchloric acid, hypochlorous acid and the like, alkylthiol compounds, aromatic thiol compounds such as aromatic thiols and fluorinated alkylaromatic thiols and the like, etc. may be provided between a source electrode and a drain electrode, and an organic semiconductor layer.

### <Production Method of Organic Thin-Film Transistor>

The organic thin-film transistor of the present invention can be produced by a production method of an organic thin-film transistor having an insulation layer, a source electrode, a drain electrode, a gate electrode and an organic semiconductor layer, comprising

a step of forming an insulation layer composed of a hardened film obtained by the method described in the above-described hardened film production method,

a step of forming a source electrode, a drain electrode and a gate electrode, and

a step of forming an organic semiconductor layer.

A substrate 1, a gate electrode 2, a source electrode 5, a drain electrode 6 and an organic semiconductor layer 4 may be constituted with materials and methods which are usually used in conventionally known production methods of an organic thin-film transistor.

As the substrate 1 a resin substrate or a resin film, a plastic substrate or a plastic film, a glass substrate, a silicon substrate and the like are used.

### (Production Method of Gate Electrode, Source Electrode, Drain Electrode)

The gate electrode 2, the source electrode 5 and the drain electrode 6 can be formed by known methods such as a vapor deposition method, a sputtering method, application methods such as an inkjet printing method and the like, using the above-described materials.

### (Production Method of Gate Insulation Layer)

The gate insulation layer 3 can be produced by the same method as the production method of a hardened film previously described.

A self-assembled monomolecular layer may be formed on the surface at the side of the organic semiconductor layer 4 of the gate insulation layer 3. This self-assembled monomolecular layer can be formed, for example, by treating the gate insulation layer 3 with a solution prepared by dissolving an alkylchlorosilane compound or an alkylalkoxysilane compound at a concentration of 1 to 10% by mass in an organic solvent.

The alkylchlorosilane compound for forming the self-assembled monomolecular layer includes, for example, methyltrichlorosilane, ethyltrichlorosilane, butyltrichlorosilane, decyltrichlorosilane, octadecyltrichlorosilane and the like.

The alkylalkoxysilane compound for forming the self-assembled monomolecular layer includes methyltrimethoxysilane, ethyltrimethoxysilane, butyltrimethoxysilane, decyltrimethoxysilane, octadecyltrimethoxysilane and the like. The application method includes a spin coating method, a die coating method, a screen printing method, an inkjet method and the like. The application solution may contain a leveling agent, a surfactant, a curing catalyst and the like, if necessary.

The organic solvent is not particularly restricted as long as it dissolves a material constituting the gate insulation layer, and solvents having a boiling point of 100° C. to 200° C. at normal pressure are preferable. The organic solvent includes 2-heptanone, propylene glycol monomethyl ether acetate (PGMEA), 2-ethoxyethanol and the like, from the standpoint of easy formation of a uniform coated film. Ketone solvents such as cyclopentanone, 2-heptanone, acetone and the like, acetate solvents such as propylene glycol monomethyl ether acetate, butyl acetate and the like and alcohol solvents such as 2-ethoxyethanol and the like are preferable, from the standpoint of scarce dissolution of other layers in lamination.

### (Production Method of Protective Layer)

The protective layer 7 (overcoat layer) can be formed, for example, by using the photosensitive composition of the present invention previously explained in the same manner as the formation step of the gate insulation layer 3 explained previously. Further, methods of covering with an UV curable resin, a thermosetting resin or an inorganic SiONₓ film and the like are also mentioned.

Further, the underlying layer (undercoat layer) not illustrated can also be formed in the same manner as for the protective layer 7.

### (Production Method of Organic Semiconductor Layer)

In the formation step of an organic semiconductor layer 4, for example, a solvent or the like is optionally added to the above-described organic semiconductor compound to prepare an application solution for forming the organic semiconductor layer 4, this is applied and the applied layer is dried. When the above-described polymer compound contained in the photosensitive composition constituting the gate insulation layer 3 has an aromatic hydrocarbon group, affinity between the photosensitive composition and the organic semiconductor compound is excellent. Hence, a uniform and flat interface can be formed between the organic semiconductor layer 4 and the gate insulation layer 3 by the above-described application step and the drying step.

The solvent which can be used for the formation step of the organic semiconductor layer 4 is not particularly restricted providing it is a solvent capable of dissolving or dispersing an organic semiconductor compound. As such a solvent, solvents having a boiling point of 50° C. to 200° C. at normal pressure are preferable. Examples of such a solvent include chloroform, toluene, anisole, 2-heptanone, xylene, propylene glycol monomethyl ether acetate and the like. The application solution for forming the organic semiconductor layer 4 can be applied on the substrate 1 or the gate insulation layer 3 by known application methods such as a spin coating method, a die coat method, a screen printing method, an inkjet printing method and the like, in the same manner as for the application solution for forming the insulation layer 3 previously explained.

### (Production Method of Bottom Gate Top Contact Type Organic Thin-Film Transistor)

The bottom gate top contact type organic thin-film transistor as one embodiment of the present invention can be produced, for example, by a method containing the following steps (I) to (V).

(I) a step of forming a gate electrode on the main surface of a substrate

(II) a step of forming a gate insulation layer on the surface of the substrate on which a gate insulation has been provided so as to cover the gate electrode

(III) a step of forming an organic semiconductor layer on the gate insulation layer

(IV) a step of forming a source electrode and a drain electrode on the organic semiconductor layer

(V) a step of forming a protective layer so as to cover the organic semiconductor layer

### (Production Method of Bottom Gate Bottom Contact Type Organic Thin-Film Transistor)

The bottom gate bottom contact type organic thin-film transistor as one embodiment of the present invention can be produced, for example, by a method containing the following steps (I) to (V).

(I) a step of forming a gate electrode on the main surface of a substrate

(II) a step of forming a gate insulation layer on the surface of the substrate on which a gate electrode has been provided so as to cover the gate electrode

(III) a step of forming a source electrode and a drain electrode on the gate insulation layer

(IV) a step of forming an organic semiconductor layer so as the cover the source electrode, the drain electrode and the gate insulation layer containing a channel region, spanning the source electrode and the drain electrode

(V) a step of forming a protective layer so as to cover the organic semiconductor layer

### (Production Method of Top Gate Bottom Contact Type Organic Thin-Film Transistor)

The top gate bottom contact type organic thin-film transistor as one embodiment of the present invention can be produced, for example, by a method containing the following steps (I) to (V).

(I) a step of forming a source electrode and a drain electrode on a substrate

(II) a step of forming an organic semiconductor layer on the substrate, spanning the source electrode and the drain electrode

(III) a step of forming a gate insulation layer on the organic semiconductor layer

(IV) a step of forming a gate electrode on the gate insulation layer

(V) a step of forming a protective layer so as to cover the gate electrode and the organic semiconductor layer

### (Production Method of Top Gate Top Contact Type Organic Thin-Film Transistor)

The top gate top contact type organic thin-film transistor as one embodiment of the present invention can be produced, for example, by a method containing the following steps (I) to (V).

(I) a step of forming an organic semiconductor layer on a substrate

(II) a step of forming a source electrode and a drain electrode, spanning the organic semiconductor layer

(III) a step of forming a gate insulation layer on the organic semiconductor layer

(IV) a step of forming a gate electrode on the gate insulation layer

(V) a step of forming a protective layer so as the cover the gate electrode and the gate insulation layer

### <Application of Organic Thin-Film Transistor>

By using the organic thin-film transistor of the present invention, a display component containing the organic thin-film transistor can be produced. Further, by using the display component containing the organic thin-film transistor, a display having the display component can be produced.

The organic thin-film transistor of the present invention can also be used for an OFET sensor. The OFET sensor is a sensor using an organic thin-film transistor (organic field-effect transistor: OFET) as a signal conversion element converting an input signal into an electric signal and outputting the electric signal, wherein sensitivity function or selectivity function is imparted into the structure of any of an electrode, an insulation layer and an organic semiconductor layer. The OFET sensor includes, for example, a biosensor, a gas sensor, an ion sensor and a humidity sensor.

For example, a biosensor has an organic thin-film transistor having the constitution as described above. The organic thin-film transistor has a probe (sensitive region) specifically interacting with the target substance, in a channel region and/or a gate insulation layer. When the concentration of the target substance changes, electric characteristics of the probe change, thus, it can function as a biosensor.

As a method of detecting the target substance in a test sample, for example, biological molecules such as nucleic acids, proteins and the like or artificially synthesized functional groups are fixed to a channel region or the surface of a gate insulation layer or a gate electrode, and these are used as a probe.

In this method, the target substance is captured with a probe provided in the organic thin-film transistor by utilizing specific affinity between substances or functional groups such as an interaction of nucleic acid chains having complementary sequences, an antigen-antibody reaction, an enzyme-substrate reaction, a receptor-ligand interaction and the like. Accordingly, a substance of a functional group having specific affinity to the target substance is selected as the probe.

A probe is fixed to a channel region or the surface of a gate insulation layer or a gate electrode by a method corresponding to the kind of the selected probe and the kind of the surface on which a probe is formed. Further, it is also possible to synthesize a probe on the surface on which a probe is formed (for example, a probe is synthesized by a nucleic acid elongation reaction). In any case, a probe-target substance complex is formed by contacting the fixed probe with a test sample and treating them under suitable conditions. A channel region and/or a gate insulation layer itself of the organic thin-film transistor may function as a probe.

The gas sensor has an organic thin-film transistor having the constitution as described above. In the organic thin-film transistor of this case, a channel region and/or a gate insulation layer functions as a gas sensitive part. When a gas to be detected contacts a gas sensitive part, electric characteristics (electric conductivity, dielectric constant and the like) of the gas sensitive part vary, thus, it can function as a gas sensor. Like the biosensor, a probe interacting with a gas to be detected is fixed to an organic thin-film transistor, and the probe and the gas are brought into contact, to change electric characteristics of the organic thin-film transistor, thus, it may be functioned as a gas sensor.

The gas to be detected includes, for example, an electron-accepting gas and an electron-donating gas. The electron-accepting gas includes, for example, halogen gases such as F₂, Cl₂ and the like, nitrogen oxide gases, sulfur oxide gases and gases of organic acids such as acetic acid and the like. The electron-donating gas, for example, an ammonia gas, gases of amines such as aniline and the like, a carbon monoxide gas and a hydrogen gas.

The organic thin-film transistor formed by using the composition of the present invention can also be used for production of a pressure sensor. The pressure sensor has an organic thin-film transistor having the constitution as described above. In this case, a channel region and/or a gate insulation layer functions as a pressure sensitive part in the organic thin-film transistor. When pressure is applied to the pressure sensitive part, electric characteristics of the pressure sensitive part vary, thus, it can function as a pressure sensitive sensor.

When a channel region functions as a pressure sensitive part, an organic thin-film transistor may further have an orientation layer for further enhancing the crystallinity of an organic semiconductor contained in the channel region. The orientation layer includes, for example, a monomolecular layer which is provided so as to be bonded to a gate insulation layer using a silane coupling agent such as hexamethyldisilazane and the like.

Further, the organic thin-film transistor formed by using the composition of the present invention can also be used for production of a conductivity modulation type sensor. The conductivity modulation type sensor of the present invention uses a conductivity measuring element as a signal conversion element for converting an input signal into an electric signal and outputting the electric signal, and is a film containing the composition of the present invention or a film obtained by imparting sensitivity function or selectivity function for the input to be detected to a film containing the composition of the present invention. The conductivity modulation type sensor detects the input to be detected as a change in conductivity of the composition of the present invention. The conductivity modulation type sensor includes, for example, a biosensor, a gas sensor, an ion sensor and a humidity sensor.

Further, the organic thin-film transistor formed by using the composition of the present invention can also be used for production of an amplifying circuit containing an organic thin-film transistor for amplifying the output signals from various sensors such as a biosensor, a gas sensor, an ion sensor, a humidity sensor, a pressure sensor and the like.

Further, the organic thin-film transistor formed by using the composition of the present invention can also be used for production of a sensor array having a plurality of integrated sensors such as a biosensor, a gas sensor, an ion sensor, a humidity sensor, a pressure sensor and the like.

Further, the organic thin-film transistor formed by using the composition of the present invention can also be used for production of a sensor array having a plurality of integrated sensors such as a biosensor, a gas sensor, an ion sensor, a humidity sensor, a pressure sensor and the like and equipped with an amplifier circuit containing an organic thin-film transistor for individually amplifying the output signal from each of the sensors.

### EXAMPLES

The present invention will be illustrated further in detail by examples below. The present invention is not limited to the examples explained below.

### (Analysis of Molecular Weight)

The number-average molecular weight and the weight-average molecular weight of a polymer compound C described later were determined using gel permeation chromatography (GPC, manufactured by Waters, trade name: Alliance GPC2000). The polymer compound C to be measured was dissolved in THF, and the solution was injected into GPC. As the mobile phase of GPC, THF was used. As the column, “PLgel 10 μm MIXED-B, 300×7.5 mm (two columns connected, manufactured by Polymer Laboratories Ltd.)” was used. As the detector, an UV detector was used.

The number-average molecular weight and the weight-average molecular weight of the polymer compound (2-1) or (2-2) were determined using gel permeation chromatography (GPC, manufactured by Tosoh Corporation). As the mobile phase of GPC, THF was used. As the column, “PLgel 10 μm MIXED-B (single column, manufactured by Agilent Technologies)” was used. As the detector, an UV detector was used.

### (Evaluation of Patterning Property)

A film (insulation layer) was produced using a photosensitive composition, and the patterning property thereof was evaluated.

An application step, a prebake step and an exposure step were carried out to produce a film, and the film thickness of the exposed part of the resultant film was measured using a stylus type film thickness meter (DEKTAK (registered trademark)), and expressed as d1.

Further, an application step, a prebake step, an exposure step and a development step were carried out, and the film thicknesses of the unexposed part and the exposed part were measured using a stylus type film thickness meter (DEKTAK (registered trademark)), and expressed as d2 and d3, respectively.

The value of (d2/d1)×100 was defined as the residual film ratio of the unexposed part after the development step.

The value of (d3/d1)×100 was defined as the residual film ratio of the exposed part after the development step.

### Synthesis Example 1-1

### Synthesis of polymer compound C

A polymer compound C was synthesized according to the following scheme.

A gas in a reaction vessel was purged with a nitrogen gas, then, the following compound B-1 (5.35 g, 3.73 mmol), the following compound B-2 (1.38 g, 3.56 mmol), tetrahydrofuran (370 mL) and bis(tri-tert-butylphosphine)palladium (95.3 mg, 5.0% by mol) were added and stirred. Into the resultant reaction solution was dropped 17.0 mL of a 3 mol/L potassium phosphate aqueous solution, and the mixture was reacted at 45° C. for 3 hours. To the resultant reaction solution was added 150 g of a 10 wt % sodium N,N-diethyldithiocarbamate trihydrate aqueous solution, and the mixture was refluxed for 3 hours. The resultant reaction solution was poured into water, toluene was added to this, and the toluene layer was extracted. The resultant toluene solution was washed with an acetic acid aqueous solution and water, then, purified using a silica gel column. The resultant toluene solution was dropped into acetone, to obtain a deposit. The resultant deposit was washed by a Soxhlet extractor using acetone as a solvent, to obtain a polymer compound C containing a repeating unit represented by the following formula. The amount of the polymer compound C obtained was 4.28 g, and the polymer compound had a polystyrene-equivalent number-average molecular weight of 9.5×10⁴ and a polystyrene-equivalent weight-average molecular weight of 2.6×10⁵.

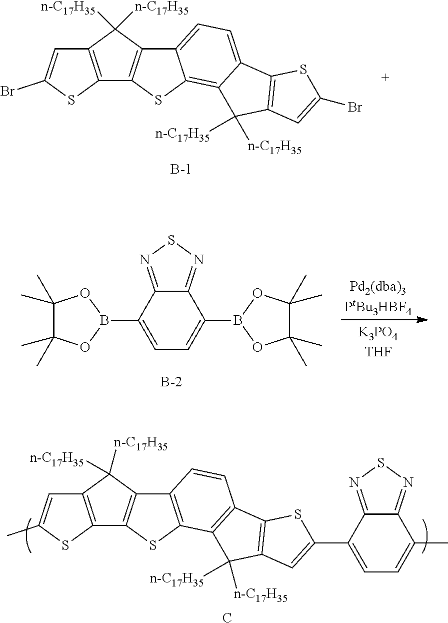

### Synthesis Example 2-1

4-Methylstyrene (manufactured by Tokyo Chemical Industry Co., Ltd.) (8.99 g: 76 mmol), 2,2,2-trifluoroethyl methacrylate (manufactured by Tosoh F-Tech Inc.) (3.19 g: 19 mmol), OTAZO-15 (manufactured by Otsuka Chemical Co., Ltd.) (0.067 g: 0.19 mmol) and propylene glycol monomethyl ether acetate (PGMEA) (manufactured by Alfa Aesar) (20.9 g) were charged in a 50 mL pressure-resistant glass vessel and an atmosphere in the vessel was purged with a nitrogen gas, then, they were polymerized for 17 hours in an oil bath of 60° C., to obtain a viscous PGMEA solution containing a dissolved polymer compound (2-1) having repeating units and the composition represented by the following formula. The resultant PGMEA solution was further diluted with PGMEA and dropped into methanol, to obtain a deposit. The resultant deposit was dried, to obtain 4.37 g of poly(4-methylstyrene-co-2,2,2-trifluoroethyl methacrylate). The resultant poly(4-methylstyrene-co-2,2,2-trifluoroethyl methacrylate) had a polystyrene-equivalent number-average molecular weight of 8.4×10⁴ and a polystyrene-equivalent weight-average molecular weight of 1.7×10⁵.

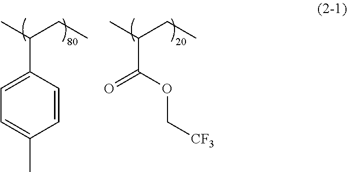

### Synthesis Example 2-2

2,2,2-Trifluoroethyl methacrylate (manufactured by Tosoh F-Tech Inc.) (3.19 g: 19 mmol), AIBN (manufactured by Wako Pure Chemical Industries, Ltd.) (0.067 g: 0.19 mmol) and propylene glycol monomethyl ether acetate (PGMEA) (manufactured by Alfa Aesar) (20.9 g) were charged in a 50 mL pressure-resistant glass vessel and an atmosphere in the vessel was purged with a nitrogen gas, then, they were polymerized for 17 hours in an oil bath of 70° C., to obtain a viscous PGMEA solution containing a dissolved polymer compound (2-2) (poly2,2,2-trifluoroethyl methacrylate). The resultant poly2,2,2-trifluoroethyl methacrylate had a polystyrene-equivalent number-average molecular weight of 3.0×10⁴ and a polystyrene-equivalent weight-average molecular weight of 8.2×10⁴.

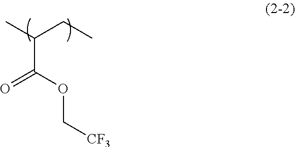

### Example 1

### (Preparation of Application Solution (a))

The polymer compound (2-1) (1.50 g) obtained in Synthesis Example 2-1, 2,6-bis(4′-azidebenzal)-4-methyl-cyclohexanone (BACM: manufactured by Toyo Gosei Co., Ltd.) (15 mg) and propylene glycol monomethyl ether acetate (PGMEA) (manufactured by Alfa Aesar) (8.50 g) were charged in a 20 mL sample bottle and dissolved by stirring, to prepare a uniform application solution (a).

### (Fabrication and Evaluation of Organic Thin-Film Transistor (1))

First, a glass substrate was irradiated with UV ozone, then, washed with an alkali washing solution, and rinsed with pure water.

Next, on the glass substrate, molybdenum and gold were laminated in this order from the substrate side by a sputtering method and patterned by photolithography, to form a source electrode and a drain electrode. The channel length of the source electrode and the drain electrode at this time was set to 20 μm and the channel width thereof was set to 2 mm.

Next, the glass substrate was ultrasonically washed with acetone, then, irradiated with UV ozone.

Next, the glass substrate was immersed in an isopropyl alcohol-diluted solution of 2,3,5,6-tetrafluoro-4-trifluoromethylbenzenethiol for 2 minutes, to modify the surface of the electrodes (particularly, gold) formed on the glass substrate.

Subsequently, a 0.5% by mass toluene solution of the polymer compound C obtained in Synthesis Example 1-1 was spin-coated on the side of the source electrode and the drain electrode, and heat-treated at 150° C. for 7 minutes using a hot plate, to form an organic semiconductor layer.

On this organic semiconductor layer, the application solution (a) was applied by a spin coating method, and dried on a hot plate at 90° C. for 1 minute. Next, it was irradiated with 200 mJ/cm² UV light (wavelength: 365 nm) using an aligner (manufactured by Canon: PLA-521). Then, it was heat-treated at 70° C. for 1 minute, and further, heat-treated at 90° C. for 10 minutes, to form a gate insulation layer. The thickness of the formed gate insulation layer was 1037 nm.

Further, a gate electrode was formed by forming a film of aluminum on this gate insulation layer by a vapor deposition method, to obtain an organic thin-film transistor (1).

Properties of the resultant organic thin-film transistor (1) were evaluated.

Specifically, the carrier mobility of the organic thin-film transistor (1) was measured and evaluated using a semiconductor parameter analyzer (4200-SCS: manufactured by Keithley) with the source-drain voltage Vsd fixed to −30V and the gate voltage Vg changing from 20 V to −40 V.

The carrier mobility of the organic thin-film transistor (1) was 0.57 cm²/Vs. The results are shown in Table 1.

The application solution (a) was filtrated through a membrane filter having a pore diameter of 0.5 μm, spin-coated on a silicon substrate (application step), then, dried on a hot plate at 90° C. for 1 minutes (prebake step), to obtain a film.

Next, the film was irradiated with 200 mJ/cm² UV light (wavelength: 365 nm) using a mask having line/space of 100 μm/100 μm and an aligner (manufactured by Canon: PLA-521) (exposure step).

Next, the film was developed by immersing in a development solution of propylene glycol monomethyl ether acetate at room temperature for 120 seconds (development step), to obtain a patterned insulation layer.

It could be visually confirmed that a pattern as per mask was obtained on the resultant insulation layer.

The thickness (d2) of the unexposed part of the resultant insulation layer was 0 nm and the thickness (d3) of the exposed part thereof was 953 nm.

Further, the thickness (d1) of the exposed part of the film executed up to the above-described exposure step was measured. The thickness (d1) was 1010 nm.

The residual film ratio of the unexposed part ((d2/d1)×100) was 0% and the residual film ratio of the exposed part ((d3/d1)×100) was 94.4%. The results are shown in Table 1.

### Example 2

### (Preparation of Application Solution (b))

The polymer compound (2-1) (1.50 g) obtained in Synthesis Example 2-1, 2,6-bis(4′-azidebenzal)-4-methyl-cyclohexanone (BACM: manufactured by Toyo Gosei Co., Ltd.) (45 mg) and propylene glycol monomethyl ether acetate (PGMEA) (manufactured by Alfa Aesar) (8.50 g) were charged in a 20 mL sample bottle and dissolved by stirring, to prepare a uniform application solution (b).

### (Fabrication and Evaluation of Organic Thin-Film Transistor (2))

An organic thin-film transistor (2) was fabricated in the same manner as in Example 1 except that the application solution (b) was used instead of the application solution (a), and carrier mobility thereof was measured. The carrier mobility was 0.17 cm²/Vs. The results are shown in Table 1.

An insulation layer executed up to the development step and a film executed up to the exposure step were obtained, respectively, in the same manner as in Example 1 except that the application solution (b) was used instead of the application solution (a). It could be visually confirmed that a pattern as per mask was obtained on the insulation layer executed up to the development step.

Next, the thickness (d2) of the unexposed part of the insulation layer obtained by executing up to the development step and the thickness (d3) of the exposed part thereof, and the thickness (d1) of the exposed part of the film executed up to the exposure step were measured, respectively.

d2 was 0 nm, d3 was 1050 nm and d1 was 1030 nm.

That is, the residual film ratio of the unexposed part ((d2/d1)×100) was 0% and the residual film ratio of the exposed part ((d3/d1)×100) was 101.9%. The results are shown in Table 1.

### Example 3

### (Preparation of Application Solution (c))

The polymer compound (2-1) (1.50 g) obtained in Synthesis Example 2-1, 2,6-bis(4′-azidebenzal)-4-methyl-cyclohexanone (BACM: manufactured by Toyo Gosei Co., Ltd.) (150 mg) and propylene glycol monomethyl ether acetate (PGMEA) (manufactured by Alfa Aesar) (8.50 g) were charged in a 20 mL sample bottle and dissolved by stirring, to prepare a uniform application solution (c).

### (Fabrication and Evaluation of Organic Thin-Film Transistor (3))

A chromium (Cr) layer formed on a glass substrate by a photolithography step and an etching step was patterned, to form a gate electrode.

Subsequently, the application solution (c) was applied by a spin coating method, and dried on a hot plate at 90° C. for 1 minute. Next, it was irradiated with 200 mJ/cm² UV light (wavelength: 365 nm) using an aligner (manufactured by Canon: PLA-521). Next, it was heat-treated at 150° C. for 20 minutes, to form a gate insulation layer. The thickness of the gate insulation layer formed was 1126 nm. Subsequently, a film of gold was formed by a vapor deposition method, to form a source electrode and a drain electrode. The channel length was 20 μm and the channel width was 2 mm. The substrate was immersed for 2 minutes in an isopropyl alcohol-diluted solution of 2,3,5,6-tetrafluoro-4-trifluoromethylbenzenethiol, to modify the surface of the source electrode and the drain electrode formed on the gate insulation layer. Subsequently, a 0.5 wt % toluene solution of the above-described polymer compound C was spin-coated, and dried on a hot plate at a temperature of 90° C. for 10 minutes, to form an organic semiconductor layer, obtaining a bottom gate bottom contact type organic thin-film transistor (3) having the constitution shown in FIG. 1.

The properties of the resultant organic thin-film transistor (3) were evaluated in the same manner as in Example 1. The carrier mobility of the organic thin-film transistor (3) was 0.82 cm²/Vs. The results are shown in Table 1.

An insulation layer executed up to the development step and a film executed up to the exposure step were obtained, respectively, in the same manner as in Example 1 except that the application solution (c) was used instead of the application solution (a). It could be visually confirmed that a pattern as per mask was obtained on the insulation layer executed up to the development step.

Next, the thickness (d2) of the unexposed part of the insulation layer obtained by executing up to the development step and the thickness (d3) of the exposed part thereof, and the thickness (d1) of the exposed part of the film executed up to the exposure step were measured, respectively.

d2 was 0 nm, d3 was 1106 nm and d1 was 1117 nm.

That is, the residual film ratio of the unexposed part ((d2/d1)×100) was 0% and the residual film ratio of the exposed part ((d3/d1)×100) was 99.0%. The results are shown in Table 1.

### Comparative Example 1

### (Preparation of Application Solution (d))

Polystyrene (manufactured by Aldrich: product No. 331651) (1.50 g), 2,6-bis(4′-azidebenzal)-4-methyl-cyclohexanone (BACM: manufactured by Toyo Gosei Co., Ltd.) (45 mg) and propylene glycol monomethyl ether acetate (PGMEA) (manufactured by Alfa Aesar) (8.50 g) were charged in a 20 mL sample bottle and dissolved by stirring, to prepare a uniform application solution (d).

### (Fabrication and Evaluation of Organic Thin-Film Transistor (4))

An organic thin-film transistor (4) was fabricated in the same manner as in Example 1 except that the application solution (d) was used instead of the application solution (a), and carrier mobility thereof was measured. The carrier mobility was 0.25 cm²/Vs. The results are shown in Table 1.

An insulation layer executed up to the development step and a film executed up to the exposure step were obtained, respectively, in the same manner as in Example 1 except that the application solution (d) was used instead of the application solution (a). In the insulation layer executed up to the development step, a pattern as per mask was not obtained. That is, the thickness (d2) of the unexposed part and the thickness (d3) of the exposed part of the insulation layer obtained by executing up to the development step were all 0 nm.

The thickness (d1) of the exposed part of the film executed up to the exposure step was measured, to find d1 of 1004 nm.

That is, the residual film ratio of the unexposed part ((d2/d1)×100) was 0% and the residual film ratio of the exposed part ((d3/d1)×100) was 0%. The results are shown in Table 1.

### Comparative Example 2

### (Preparation of Application Solution (e))

Polystyrene (manufactured by Aldrich: product No. 331651) (1.50 g), 2,6-bis(4′-azidebenzal)-4-methyl-cyclohexanone (BACM: manufactured by Toyo Gosei Co., Ltd.) (150 mg) and propylene glycol monomethyl ether acetate (PGMEA) (manufactured by Alfa Aesar) (8.50 g) were charged in a 20 mL sample bottle and dissolved by stirring, to prepare a uniform application solution (e).

### (Fabrication and Evaluation of Organic Thin-Film Transistor (5))

An organic thin-film transistor (5) was fabricated in the same manner as in Example 3 except that the application solution (e) was used instead of the application solution (c).

The thickness of the gate insulation layer was 1066 nm as measured before vapor-depositing a gold electrode, however, in spin-coating the above-described 0.5 wt % toluene solution of the polymer compound C, the gate insulation layer was partially dissolved and the thickness of the gate insulation layer became thinner to 360 nm. Hence, the gate leakage current increased, transistor operation could not be obtained, and the carrier mobility could not be measured.

An insulation layer executed up to the development step and a film executed up to the exposure step were obtained, respectively, in the same manner as in Example 1 except that the application solution (e) was used instead of the application solution (a). In the insulation layer executed up to the development step, a pattern as per mask could not be obtained. That is, the thickness (d2) of the unexposed part and the thickness (d3) of the exposed part of the insulation layer obtained by executing up to the development step were all 0 nm.

The thickness (d1) of the exposed part of the film executed up to the exposure step was measured, to find d1 of 1062 nm.

That is, the residual film ratio of the unexposed part ((d2/d1)×100) was 0% and the residual film ratio of the exposed part ((d3/d1)×100) was 0%. The results are shown in Table 1.

### Comparative Example 3

### (Preparation of Application Solution (f))

The polymer compound (2-2) (1.50 g) obtained in Synthesis Example 2-2, 2,6-bis(4′-azidebenzal)-4-methyl-cyclohexanone (BACM: manufactured by Toyo Gosei Co., Ltd.) (45 mg) and propylene glycol monomethyl ether acetate (PGMEA) (manufactured by Alfa Aesar) (8.50 g) were charged in a 20 mL sample bottle and dissolved by stirring, to prepare a uniform application solution (f).

### (Fabrication and Evaluation of Organic Thin-Film Transistor (6))

An organic thin-film transistor (6) was fabricated in the same manner as in Example 1 except that the application solution (f) was used instead of the application solution (a), and carrier mobility thereof was measured. The carrier mobility was 0.00034 cm²/Vs. The results are shown in Table 1.

An insulation layer executed up to the development step and a film executed up to the exposure step were obtained, respectively, in the same manner as in Example 1 except that the application solution (f) was used instead of the application solution (a). In the insulation layer executed up to the development step, a pattern as per mask could not be obtained. That is, the thickness (d2) of the unexposed part and the thickness (d3) of the exposed part of the insulation layer obtained by executing up to the development step were all 0 nm.

The thickness (d1) of the exposed part of the film executed up to the exposure step was measured, to find d1 of 1055 nm.

That is, the residual film ratio of the unexposed part ((d2/d1)×100) was 0% and the residual film ratio of the exposed part ((d3/d1)×100) was 0%. The results are shown in Table 1.

TABLE 1

| | | presence or absence | residual film |
|---|---|---|---|
| | carrier | of formation of mask | ratio of exposed |
| | mobility | pattern after | part |
| | (cm²/Vs) | development step | (%) |
| Example 1 | 0.57 | ◯ (presence) | 94.4 |
| Example 2 | 0.17 | ◯ (presence) | 101.9 |
| Example 3 | 0.82 | ◯ (presence) | 99.0 |
| Comparative | 0.25 | X (absence) | 0 |
| Example 1 | | | |
| Comparative | No operation | X (absence) | 0 |
| Example 2 | of transistor | | |
| Comparative | 0.00034 | X (absence) | 0 |
| Example 3 | | | |

As apparent from Table 1, the photosensitive compositions fabricated in Examples 1 to 3 are excellent in a patterning property, and the film transistors having an insulation layer composed of the photosensitive composition exhibit high carrier mobility.

### EXPLANATION OF NUMERALS

1: substrate,

2: gate electrode,

3: gate insulation layer,

4: organic semiconductor layer,

5: source electrode,

6: drain electrode,

7: overcoat layer (protective layer),

10: organic thin-film transistor.

1. A photosensitive composition comprising a polymer compound composed of a repeating unit represented by the following formula (1) and at least one repeating unit selected from the group consisting of a repeating unit represented by the following formula (2), a repeating unit represented by the following formula (3) and a repeating unit represented by the following formula (4), and a compound having at least two azide groups: 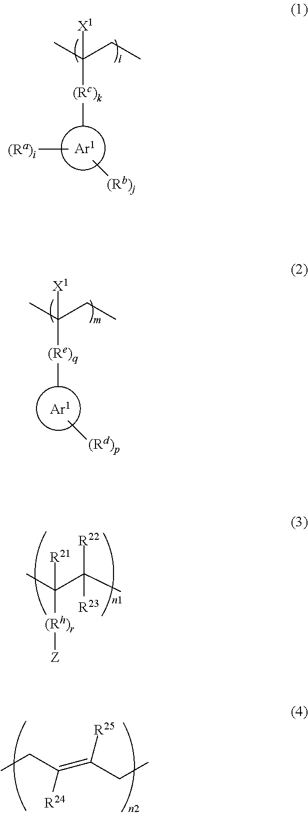
wherein, in the formula (1), Ar¹ represents a phenyl group or a naphthyl group,
R^{a} is a group represented by the following formula (5); when a plurality of R^{a} are present, they may be the same or different and may be combined together to form a ring together with a carbon atom on Ar¹ to which they are attached,
R^{b} is a hydrogen atom, a fluorine atom, a phenyl group optionally having a substituent, a naphthyl group optionally having a substituent or a group represented by the following formula (6); when a plurality of R^{b} are present, they may be the same or different,
when Ar¹ is a phenyl group, i represents an integer of 1 to 5 and j represents an integer of 5-i,
when Ar¹ is a naphthyl group, i represents an integer of 1 to 7 and j represents an integer of 7-i,
X¹ represents a hydrogen atom or a methyl group,
R^{c} represents a divalent organic group having a number of carbon atoms of 1 to 20, a group represented by —O— or a group represented by —C(═O)—, and
k represents an integer of 0 to 6;
in the formula (2), Ar² represents a phenyl group or a naphthyl group,
a plurality of R^{d} are each a hydrogen atom, a fluorine atom, a phenyl group optionally having a substituent, a naphthyl group optionally having a substituent or a group represented by the following formula (6), a plurality of R^{d} may be the same or different,
when Ar² is a phenyl group, p represents 5,
when Ar² is a naphthyl group, p represents 7,
X² represents a hydrogen atom or a methyl group,
R^{e} represents a divalent organic group having a number of carbon atoms of 1 to 20, a group represented by —O— or a group represented by —C(═O)—, and
q represents an integer of 0 to 6;
in the formula (3), R^{2 1}, R^{2 2} and R^{2 3} are each independently a hydrogen atom, a fluorine atom or an alkyl group having a number of carbon atoms of 1 to 20, and R^{2 1}, R^{2 2}, R^{2 3} and Z may be combined together to form a ring,
Z represents an alkyl group having a number of carbon atoms of 1 to 20 or an alkenyl group having a number of carbon atoms of 2 to 20,
A hydrogen atom contained in the group represented by Z may be substituted with a fluorine atom,
R^{h} represents a divalent organic group having a number of carbon atoms of 1 to 20, a group represented by —O— or a group represented by —C(═O)—, and
r represents an integer of 0 to 6;
in the formula (4), R^{2 4} and R^{2 5} each independently represent a hydrogen atom or an alkyl group having a number of carbon atoms of 1 to 20,
l, m, n1 and n2 are numbers satisfying l≥15 and m+n1+n2=100-l, and l+n2≥10 when the total amount of all repeating units contained in said polymer compound is taken as 100: 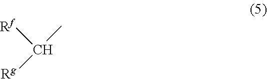
wherein, in the formula (5), R^{f} and R^{g} are each independently a hydrogen atom, a fluorine atom or a hydrocarbon group optionally substituted with a fluorine atom, and R^{f} and R^{g} may be combined together to form a ring: 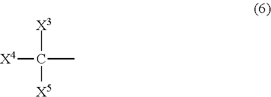
wherein, in the formula (6), X³, X⁴ and X⁵ are each independently a fluorine atom or a hydrocarbon group optionally substituted with a fluorine atom.

2. The photosensitive composition according to claim 1, wherein in said polymer compound, Ar¹ in the repeating unit represented by the formula (1) is a phenyl group.

3. The photosensitive composition according to claim 1, wherein in said polymer compound, Ar² in the repeating unit represented by the formula (2) is a phenyl group.

4. The photosensitive composition according to claim 1, wherein in said repeating unit represented by the formula (1), the group represented by R^{a} is a methyl group.

5. The photosensitive composition according to claim 1, wherein in said repeating unit represented by the formula (1), k is 0.

6. The photosensitive composition according to claim 1, wherein in said repeating unit represented by the formula (3), r is 0 to 3.

7. The photosensitive composition according to claim 1, wherein said compound having at least two azide groups is a compound represented by the following formula (7): 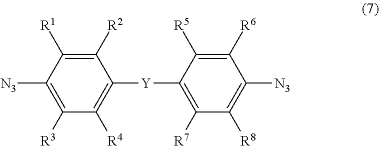
wherein, in the formula (7),
R¹ to R⁸ each independently represent a hydrogen atom, a fluorine atom, an alkyl group having a number of carbon atoms of 1 to 5, an alkoxy group having a number of carbon atoms of 1 to 5 or a group represented by SO₃M, wherein M represents a hydrogen atom, an alkali metal atom, an alkyl group having a number of carbon atoms of 1 to 10 or NR^{A}R^{B}, and R^{A} and R^{B} each independently represent a hydrogen atom, an alkyl group having a number of carbon atoms of 1 to 10, a hydroxyalkyl group having a number of carbon atoms of 1 to 10, an alkoxyalkyl group having a number of carbon atoms of 1 to 10 or a hydroxyalkoxyalkyl group having a number of carbon atoms of 1 to 10, and
Y represents a single bond, a group represented by —C(═O)—, a group represented by —S—, an alkylene group having a number of carbon atoms of 1 to 8 or a divalent group represented by any one of the following formula (7-1) to the following formula (7-4), wherein in the formula (7-4), R⁹ is a hydrogen atom or an alkyl group having a number of carbon atoms of 1 to 10:

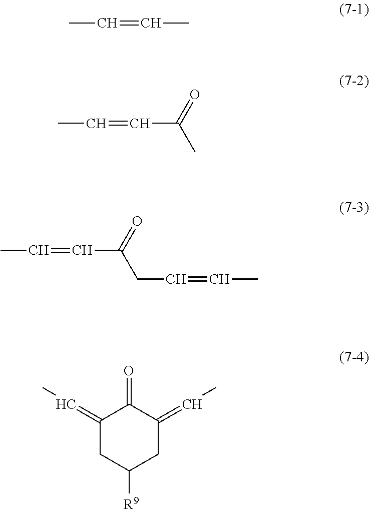

8. An ink comprising the photosensitive composition according to claim 1 and an organic solvent.

9. A film obtained by hardening the photosensitive composition according to claim 1.

10. An electronic device comprising the film according to claim 9.

11. An organic thin-film transistor comprising the film according to claim 9 as an insulation layer.

12. An organic thin-film transistor comprising the film according to claim 9 as a gate insulation layer.

13. A production method of a hardened film, comprising
a step of applying the ink according to claim 8 on an object to obtain a film,
a step of heating said film to remove the organic solvent, and
a step of exposing said organic solvent-removed film.

14. A production method of an organic thin-film transistor having an insulation layer, a source electrode, a drain electrode, a gate electrode and an organic semiconductor layer, comprising
a step of forming an insulation layer composed of the hardened film obtained by the production method according to claim 13,
a step of forming a source electrode, a drain electrode and a gate electrode, and
a step of forming an organic semiconductor layer.
